(19) United States
(12) Patent Application Publication
(10) Pub. No.: US 2025/0254865 A1
(43) Pub. Date: Aug. 7, 2025

(54) SEMICONDUCTOR MEMORY DEVICE

(71) Applicant: Samsung Electronics Co., Ltd., Suwon-si (KR)

(72) Inventors: Bowon YOO, Suwon-si (KR); Taegyu KANG, Suwon-si (KR); Yujin KIM, Suwon-si (KR); Seokhan PARK, Suwon-si (KR); Gyuhwan OH, Suwon-si (KR); Jinwoo HAN, Suwon-si (KR)

(73) Assignee: Samsung Electronics Co., Ltd., Suwon-si (KR)

(21) Appl. No.: 18/806,865

(22) Filed: Aug. 16, 2024

(30) Foreign Application Priority Data
Feb. 6, 2024 (KR) 10-2024-0018425

(51) Int. Cl. H10B 12/00

(52) U.S. Cl. CPC H10B 12/488; H10B 12/315; H10B 12/482

(57) ABSTRACT

A semiconductor memory device includes active regions arranged at a first vertical level on a substrate, a thickness of each active region in a vertical direction varying in a first lateral direction, a first word line surrounding first active regions belonging to a first group of the active regions, a second word line surrounding second active regions belonging to a second group of the active regions, the second word line being apart from the first word line in the first lateral direction, and a pair of word line pads being at the first vertical level on the substrate, the pair of word line pads being connected to the first word line and the second word line, respectively.

### CROSS-REFERENCE TO RELATED APPLICATION

This application is based on and claims priority under 35 U.S.C. § 119 to Korean Patent Application No. 10-2024-0018425, filed on Feb. 6, 2024, in the Korean Intellectual Property Office, the disclosure of which is incorporated by reference herein in its entirety.

### BACKGROUND

The inventive concepts relate to semiconductor memory devices, and more particularly, to semiconductor memory devices including a plurality of memory cells arranged three-dimensionally.

The downscaling of semiconductor devices has rapidly progressed due to the development of electronics technology. Thus, the miniaturization of memory cells is required, and current memory cells have limitations in maintaining high integration and reliability. Accordingly, there is a need to develop a semiconductor memory device configured to facilitate the miniaturization and high integration of memory cells.

### SUMMARY

The inventive concepts provide semiconductor memory devices configured to facilitate the miniaturization and high integration of memory cells.

According to an example embodiment of the inventive concepts, a semiconductor memory device may include a plurality of active regions repeatedly arranged in a first lateral direction and a second lateral direction at a first vertical level, the first vertical level being apart from a substrate in a vertical direction, a thickness in the vertical direction of each active region varying in the first lateral direction, the first lateral direction and the second lateral direction being perpendicular to each other, a first word line surrounding a plurality of first active regions belonging to a first group, the first word line extending lengthwise in the second lateral direction at the first vertical level, and the plurality of first active regions being selected from the plurality of active regions and arranged in a line in the second lateral direction, a second word line surrounding a plurality of second active regions belonging to a second group, the second word line extending lengthwise in the second lateral direction at the first vertical level, the plurality of second active regions being selected from the plurality of active regions and arranged in a line in the second lateral direction, the second word line being apart from the first word line in the first lateral direction, a pair of word line pads being at the first vertical level on the substrate, and the pair of word line pads being connected to the first word line and the second word line, respectively.

According to an example embodiment of the inventive concepts, a semiconductor memory device may include a memory cell block having a three-dimensional (3D) structure, the memory cell block including a plurality of memory cells repeatedly arranged on a substrate in a first lateral direction, a second lateral direction, and a vertical direction perpendicular to the substrate, the first lateral direction and the second lateral direction being perpendicular to each other, and at least one dummy block located around the memory cell block, wherein the memory cell block includes a first active region and a second active region on the substrate at a first vertical level, the first active region and the second active region being apart from each other in the first lateral direction, a thickness of each of the first active region and the second active region varying in the first lateral direction, a first word line surrounding a portion of the first active region and extending lengthwise in the second lateral direction at the first vertical level, a second word line surrounding the second active region and extending lengthwise in the second lateral direction at the first vertical level, the second word line being apart from the first word line in the first lateral direction, and a pair of word line pads being at the first vertical level on the substrate, the pair of word line pads being apart from each other in the second lateral direction with the first word line and the second word line therebetween, the pair of word line pads connected to the first word line and the second word line, respectively, and wherein the at least one dummy block includes a plurality of sacrificial layers and a plurality of active layers, which are alternately stacked one-by-one on the substrate in the vertical direction, each of the plurality of active layers, the first active region, and the second active region includes a first semiconductor material, and each of the plurality of sacrificial layers includes a second semiconductor material, the second semiconductor material being different from the first semiconductor material, and a thickness of each of the plurality of active layers is greater than a thickness of each of the plurality of sacrificial layers in the vertical direction.

According to an example embodiment of the inventive concepts, a semiconductor memory device may include a memory cell block having a three-dimensional (3D) structure, the memory cell block including a plurality of memory cells repeatedly arranged on a substrate in a first lateral direction, a second lateral direction, and a vertical direction perpendicular to the substrate, the first lateral direction and the second lateral direction being perpendicular to each other, and at least one dummy block located around the memory cell block, wherein the memory cell block includes a plurality of active regions repeatedly arranged at a vertical level on the substrate in the first lateral direction and the second lateral direction, a thickness of each of the plurality of active regions in the vertical direction varying in the first lateral direction, the plurality of active regions including a first group of active regions and a second group of active regions, a first word line surrounding the first group of active regions, the first word line extending lengthwise in the second lateral direction at a first vertical level, of the first group active regions being selected from the plurality of active regions and arranged in a line in the second lateral direction, a second word line surrounding the second group of active regions, the second word line extending lengthwise in the second lateral direction at the first vertical level, the second group of active regions being selected from the plurality of active regions and arranged in a line in the second lateral direction, the second word line being apart from the first word line in the first lateral direction, a first word line pad and a second word line pad being apart from each other in the second lateral direction with first word line and the second word line therebetween at the first vertical level, a plurality of bit lines extending lengthwise in the vertical direction on the substrate, the plurality of bit lines being connected to corresponding ones of the plurality of active regions, respectively, at the first vertical level, and a plurality of capacitors connected to corresponding ones of the plurality of active regions, respectively, wherein, when viewed from above a horizontal cross-section of the memory block at the first vertical level, the first word line and the second word line are offset from each other in the second lateral direction, and the at least one dummy block includes a plurality of sacrificial layers and a plurality of active layers, which are alternately stacked one-by-one on the substrate in the vertical direction, each of the plurality of sacrificial layers includes a silicon (Si) layer, an undoped silicon germanium (SiGe) layer, or a SiGe layer doped with carbon (C) atoms, each of the plurality of active layers includes a Si layer, and a thickness of each of the plurality of active layers is greater than a thickness of each of the plurality of sacrificial layers in the vertical direction.

### BRIEF DESCRIPTION OF THE DRAWINGS

Example embodiments will be more clearly understood from the following detailed description taken in conjunction with the accompanying drawings in which:

FIG. 1 is a block diagram of a semiconductor memory device according to an example embodiment;

FIG. 2 is a plan view of a memory cell block of a semiconductor memory device according to an example embodiment;

FIG. 3 is a plan view of some components at a vertical level in a memory cell block of a semiconductor memory device according to an example embodiment;

FIG. 4 is a cross-sectional view taken along line X1-X1′ of FIG. 2, illustrating a first region and a second region of the memory cell block shown in FIG. 2;

FIG. 5 is a cross-sectional view taken along line X1-X1′ of FIG. 2, illustrating a third region of the memory cell block shown in FIG. 2;

FIG. 6 is an enlarged cross-sectional view of a partial region “EX0” of FIG. 5;

FIG. 7 is a cross-sectional view taken along line Y1-Y1′ of FIG. 2, which illustrates the memory cell block shown in FIG. 2;

FIG. 8 is a plan view of a semiconductor memory device according to an example embodiment;

FIG. 9 is a cross-sectional view taken along line XD-XD′ of FIG. 8;

FIG. 10A is a perspective view of a partial region of a semiconductor memory device according to an example embodiment;

FIG. 10B is a plan view of a partial region of the semiconductor memory device shown in FIG. 10A; and

FIGS. 11A to 47C are diagrams illustrating a method of manufacturing a semiconductor memory device, according to an example embodiment, wherein FIGS. 11A, 12A, 13A, and 16A are perspective views of a process sequence of a method of manufacturing a semiconductor memory device; FIGS. 11B, 17A, 18A, 19A, 21A, 23A, 26A, 37A, 39A, 40A, and 41A are plan views of a process sequence of a method of manufacturing a semiconductor memory device; FIGS. 18B, 19B, 20A, 21B, 22A, 25A, 36A, 37B, 38A, 41B, and 47A are plan views of a partial region on a plane at a first vertical level shown in FIG. 4; FIGS. 11C, 12B, 13B, 14, 15, 16B, 18C, 19C, 20B, 21C, 22B, 23B, 24A, 25B, 26B, 36B, 38B, 39B, and 40B are cross-sectional views of partial regions of the first region and the second region of FIG. 2, which correspond to a cross-section taken along line X1-X1′ of FIG. 2, according to a process sequence; FIGS. 39C, 40C, 41C, and 47B are cross-sectional views of a partial region of the third region of FIG. 2, which corresponds to a cross-section taken along line X1-X1′ of FIG. 2, according to a process sequence; FIGS. 17B, 19D, 20C, 23C, 24B, 25C, 26C, 29A, 30A, 31, 36C, and 37C are cross-sectional views of a partial region corresponding to a cross-section taken along line Y1-Y1′ of FIG. 2, according to a process sequence; and FIGS. 26D, 27, 28, 29B, 30B, 32, 33, 34, 35, 38C, 39D, 41D, 42, 43, 44, 45, 46, and 47C are enlarged cross-sectional views of partial regions of the first region and the second region of FIG. 2, which correspond to a cross-section X1-X1′ or a cross-section Y1-Y1′ of FIG. 2, according to a process sequence.

### DETAILED DESCRIPTION

Hereinafter, some example embodiments will be described in detail with reference to the accompanying drawings. The same reference numerals are used to denote the same elements in the drawings, and repeated descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

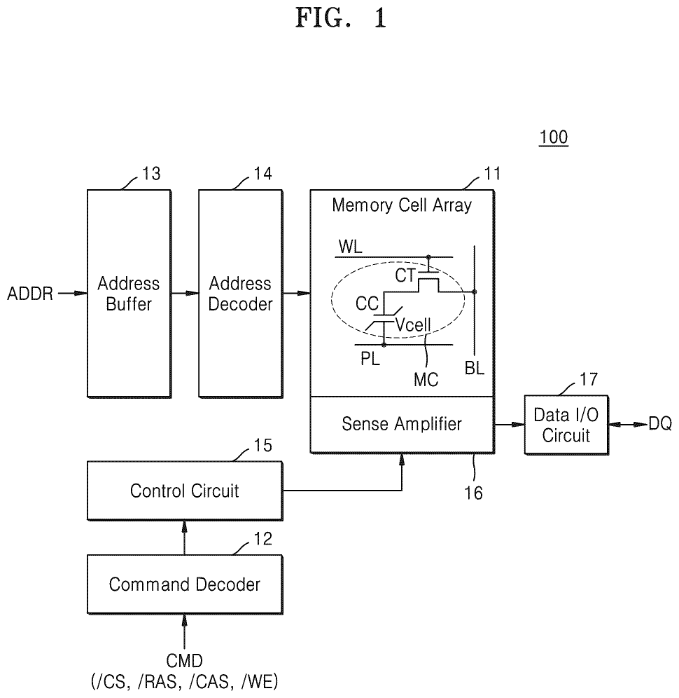

FIG. 1 is a block diagram of a semiconductor memory device 100 according to an example embodiment.

Referring to FIG. 1, the semiconductor memory device 100 may include a memory cell array 11, a command decoder 12, an address buffer 13, an address decoder 14, a control circuit 15, a sense amplifier 16, and a data input/output (I/O) circuit 17.

The memory cell array 11 may include a plurality of memory cells MC. The memory cell array 11 may include a plurality of word lines WL, a plurality of bit lines BL, and a plurality of plate electrodes PL, which are connected to the memory cells MC. The memory cell array 11 may include dynamic random access memory (DRAM) configured to sense a cell voltage Vcell stored in the memory cell MC as data.

The semiconductor memory device 100 may receive and output data DQ in response to a command CMD and an address ADDR, which are received from an external device (e.g., a central processing unit (CPU) or a memory controller).

Each of the plurality of memory cells MC may include a cell transistor CT and a cell capacitor CC. A gate of the cell transistor CT may be connected to the word line WL. A first end of the cell transistor CT may be connected to the bit line BL. A second end of the cell transistor CT may be connected to a first end of the cell capacitor CC. A second end of the cell capacitor CC may be connected to the plate electrode PL. The memory cell MC may store the cell voltage Vcell having a desired (or alternatively, predetermined) magnitude as data in the cell capacitor CC.

The command decoder 12 may determine the input command CMD by referring to a chip selection signal/CS, a row address strobe signal/RAS, a column address strobe signal/CAS, and a write enable signal/WE, which are applied from the external device. The command decoder 12 may generate control signals corresponding to the command CMD. The command CMD may include an active command, a read command, a write command, and a precharge command.

The address buffer 13 may receive the address ADDR applied from the external device. The address ADDR may include a word line address for addressing some of the plurality of word lines WL connected to the memory cell array 11, a bit line address for addressing some of the plurality of bit lines BL connected to the memory cell array 11, and a plate line address for addressing some of the plurality of plate electrodes PL connected to the memory cell array 11. The address buffer 13 may transmit each of the word line address, the bit line address, and the plate line address to the address decoder 14.

The address decoder 14 may include a word line decoder, a bit line decoder, and a plate line decoder, which are configured to select the word line WL, the bit line BL, and the plate electrode PL of the memory cell MC to be accessed, respectively, in response to the received address ADDR. The word line decoder may decode the word line address and enable the word line WL of the memory cell MC corresponding to the word line address. The bit line decoder may decode the bit line address and provide a bit line selection signal BLS for selecting the bit line BL of the memory cell MC corresponding to the bit line address. The plate line decoder may decode the plate line address and provide a plate line selection signal PLS for selecting the plate electrode PL of the memory cell MC corresponding to the plate line address.

The control circuit 15 may control the sense amplifier 16 via the control by the command decoder 12. The control circuit 15 may control the sense amplifier 16 to sense the cell voltage Vcell of the memory cell MC. The control circuit 15 may control the sense amplifier 16 to perform a precharge operation, a charge sharing operation, and a sense operation.

The sense amplifier 16 may sense charges stored in the memory cell MC as data. In addition, the sense amplifier 16 may transmit sensed data DQ to the data I/O circuit 17 such that the sensed data DQ is output to the outside of the semiconductor memory device 100.

The data I/O circuit 17 may receive data DQ to be written to the memory cell MC from the outside and transmit the data DQ to the memory cell array 11. The data I/O circuit 17 may output bit data sensed by the sense amplifier 16 as read data to the outside.

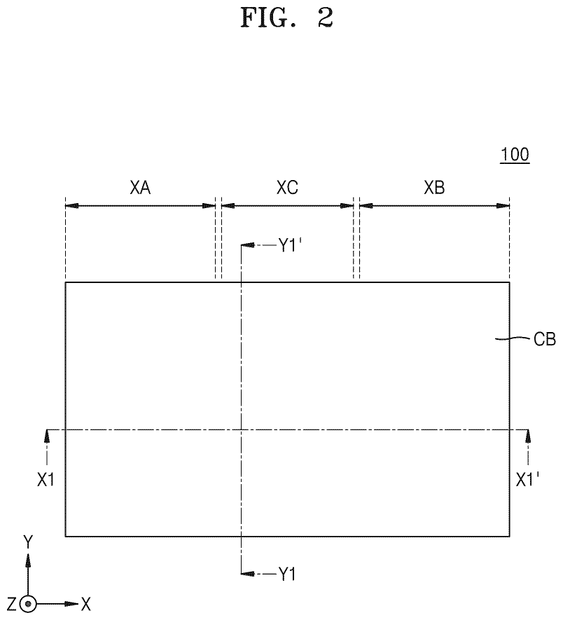

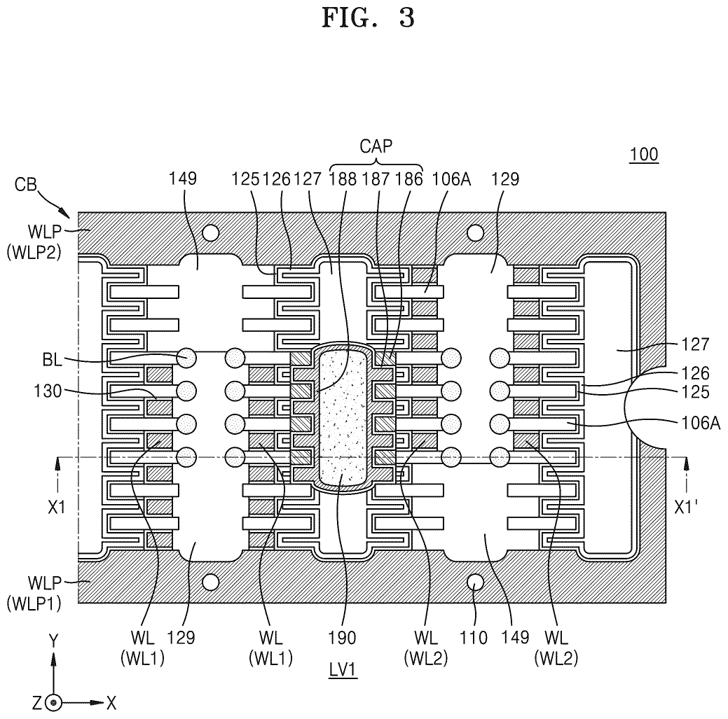

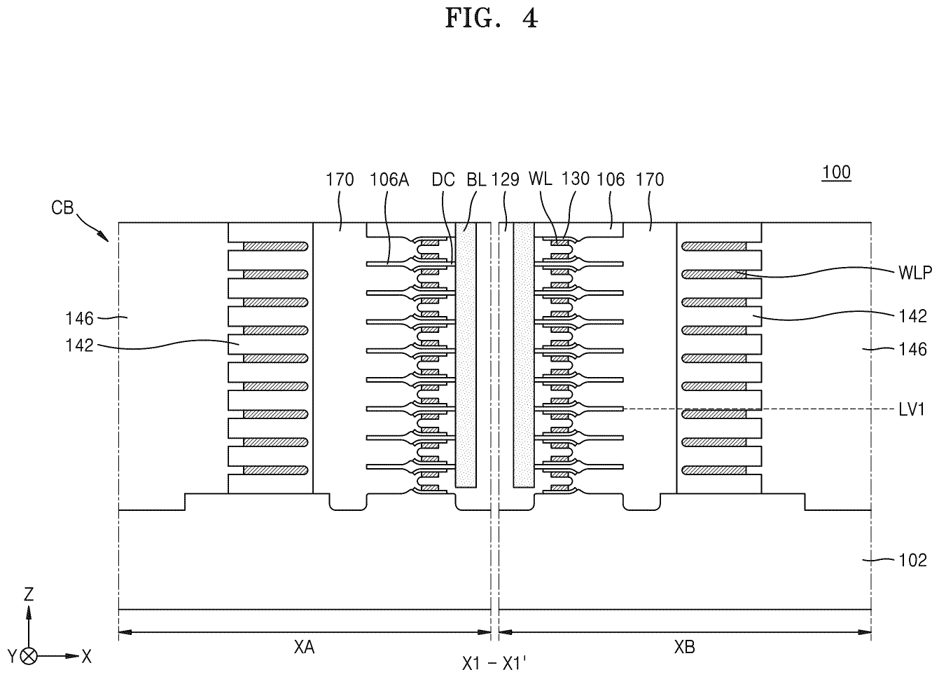

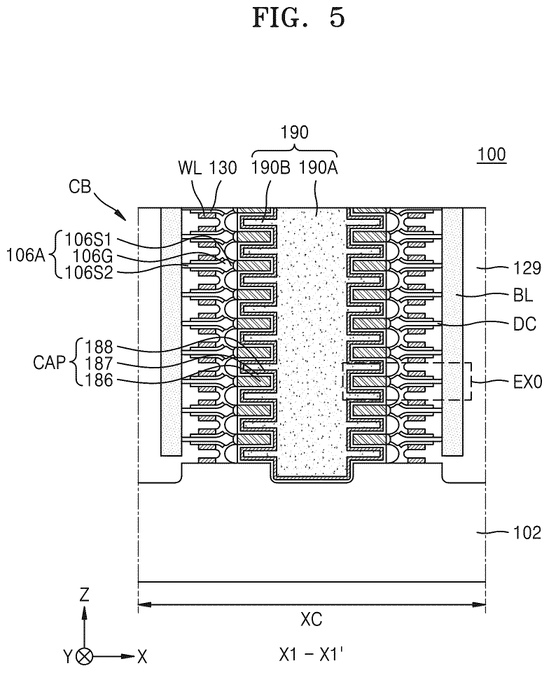

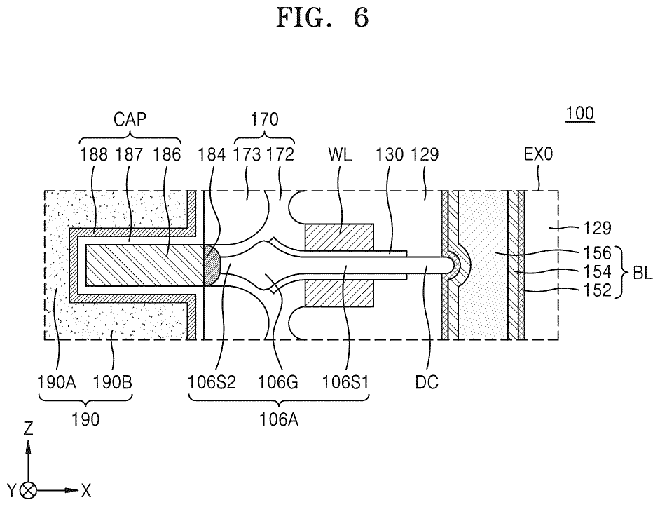

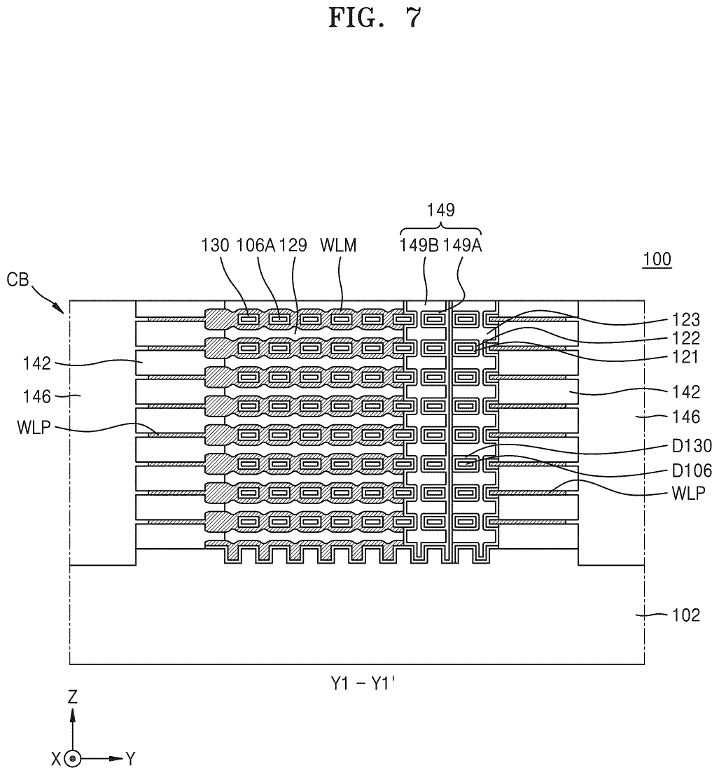

FIGS. 2 to 7 are diagrams of a memory cell block CB of a semiconductor memory device 100 according to some example embodiments. More specifically, FIG. 2 is a plan view of the memory cell block CB of the semiconductor memory device 100 according to an example embodiment. FIG. 3 is a plan view of some components of the memory cell block CB shown in FIG. 2 at a vertical level. FIG. 4 is a cross-sectional view taken along line X1-X1′ of FIG. 2, illustrating a first region XA and a second region XB of the memory cell block CB shown in FIG. 2. FIG. 5 is a cross-sectional view taken along line X1-X1′ of FIG. 2, illustrating a third region XC of the memory cell block CB shown in FIG. 2. FIG. 6 is an enlarged cross-sectional view of a partial region “EX0” of FIG. 5. FIG. 7 is a cross-sectional view taken along line Y1-Y1′ of FIG. 2, which illustrates the memory cell block CB shown in FIG. 2. The memory cell block CB shown in FIGS. 2 to 7 may constitute the memory cell array 11 described with reference to FIG. 1.

Referring to FIGS. 2 to 7, the memory cell block CB of the semiconductor memory device 100 may include a plurality of memory cells, which are repeatedly arranged in a first lateral direction (X direction) and a second lateral direction (Y direction), which are perpendicular to each other on a substrate 102, and in a vertical direction (Z direction) that is perpendicular to the substrate 102.

The memory cell block CB may include a plurality of active regions 106A, which are repeatedly arranged in the first lateral direction (X direction) and the second lateral direction (Y direction) at each of a plurality of vertical levels that are apart from the substrate 102 in the vertical direction (Z direction). In some example embodiments, each of the plurality of active regions 106A may include a doped Si layer.

As shown in FIGS. 5 and 6, a thickness of each of the plurality of active regions 106A in the vertical direction (Z direction) may be variable in the first lateral direction (X direction). Each of the plurality of active regions 106A may include a vertical protruding local portion 106G, a first local portion 106S1, and a second local portion 106S2. The first local portion 106S1 may extend from the vertical protruding local portion 106G in one direction, and the second local portion 106S2 may extend from the vertical protruding local portion 106G in another direction that is opposite to the first local portion 106S1. The vertical protruding local portion 106G, the first local portion 106S1, and the second local portion 106S2 may be integrally connected to each other and constitute one active region 106A. In each of the plurality of active regions 106A, from among the vertical protruding local portion 106G, the first local portion 106S1, and the second local portion 106S2, the vertical protruding local portion 106G may have a greatest thickness in the vertical direction (Z direction). For example, in the vertical direction (Z direction), the vertical protruding local portion 106G may have a first thickness selected in a range of about 2 nm to about 50 nm, the first local portion 106S1 may have a second thickness selected in a range of about 2 nm to about 50 nm, and the second local portion 106S2 may have a third thickness selected in a range of about 2 nm to about 50 nm. Each of the second thickness and the third thickness may be less than the first thickness. The second thickness may substantially be the same as or different from the third thickness. In the first lateral direction (X direction), a length of the first local portion 106S1 may be greater than a length of the second local portion 106S2.

The memory cell block CB of the semiconductor memory device 100 may include a plurality of word lines WL, which extend lengthwise in the second lateral direction (Y direction) at each of the plurality of vertical levels that are apart from the substrate 102 in the vertical direction (Z direction). The plurality of word lines WL may be apart from each other in the first lateral direction (X direction).

The plurality of word lines WL may include a plurality of first word lines WL1 and a plurality of second word lines WL2, which are misaligned (e.g., offset) from each other in opposite directions in the second lateral direction (Y direction) in a view from above, at each of the plurality of vertical levels that are apart from the substrate 102 in the vertical direction (Z direction). FIG. 3 illustrates some components on a plane (X-Y plane) that runs across a plurality of active regions 106A at a desired (or alternatively, predetermined) vertical level (e.g., a first vertical level LV1 shown in FIG. 4) of the memory cell block CB shown in FIG. 2. As shown in FIG. 3, the plurality of first word lines WL1 may be at a position biased in one direction (e.g., Y direction in FIG. 3) from the center of the memory cell block CB in the second lateral direction (Y direction), and the plurality of second word lines WL2 may be at a position biased in another direction (e.g., +Y direction in FIG. 3) from the center of the memory cell block CB in the second lateral direction (Y direction).

Each of the plurality of word lines WL may surround a local area of a corresponding one of a plurality of active regions 106A, which are arranged in a line in the second lateral direction (Y direction) at the same vertical level as the corresponding one of the plurality of word lines WL. The local area surrounded by the word line WL in each of the plurality of active regions 106A may be an area outside the vertical protruding local portion 106G. Each of the plurality of word lines WL may surround the first local portion 106S1 of a corresponding one of the plurality of active regions 106A, which are arranged in a line in the second lateral direction (Y direction) at the same vertical level as the corresponding one of the plurality of word lines WL.

The plurality of first word lines WL1 may surround a plurality of active regions 106A belonging to a first group and extend lengthwise in the second lateral direction (Y direction). The plurality of active regions 106A belonging to the first group may be selected from the plurality of active regions 106A, which are at each of the plurality of vertical levels apart from the substrate 102 in the vertical direction (Z direction), and may be arranged in a line in the second lateral direction (Y direction). As used herein, the active region 106A belonging to the first group may be referred to as a first active region. The plurality of second word lines WL2 may surround a plurality of active regions 106A belonging to a second group and extend lengthwise in the second direction (Y direction). The plurality of active regions 106A belonging to the second group may be selected from the plurality of active regions 106A, which are at each of the plurality of vertical levels apart from the substrate 102 in the vertical direction (Z direction), and may be arranged in a line in the second lateral direction (Y direction). As used herein, the active region 106A belonging to the second group may be referred to as a second active region. The plurality of second word lines WL2 may be apart from the plurality of first word lines WL1 in the first lateral direction (X direction).

The memory cell block CB of the semiconductor memory device 100 may include a plurality of word line pads WLP, which are connected to at least one first word line WL1 or at least one second word line WL2. As shown in FIGS. 4 and 7, the plurality of word line pads WLP may overlap each other in the vertical direction (Z direction) from the substrate 102. As shown in FIG. 3, at each of the plurality of vertical levels apart from the substrate 102 in the vertical direction (Z direction), the plurality of word line pads WLP may include a first word line pad WLP1 connected to the plurality of first word lines WL1 and a second word line pad WLP2 connected to the plurality of second word lines WL2. The first word line pad WLP1 and the second word line pad WLP2 may be apart from each other with the plurality of first word lines WL1 and the plurality of second word lines WL2 therebetween in the second lateral direction (Y direction). Each of the first word line pad WLP1 and the second word line pad WLP2 may have a planar shape extending lengthwise in the first lateral direction (X direction) to face the plurality of first word lines WL1 and the plurality of second word lines WL2 in the second lateral direction (Y direction).

In some example embodiments, the plurality of word lines WL and the plurality of word line pads WLP may include the same conductive material. In other example embodiments, at least some of the plurality of word lines WL and the plurality of word line pads WLP may include different materials. In some example embodiments, each of the plurality of word lines WL and the plurality of word line pads WLP may include metal, conductive metal nitride, metal silicide, doped polysilicon, or a combination thereof. For example, each of the plurality of word lines WL and the plurality of word line pads WLP may include titanium (Ti), titanium nitride (TiN), tantalum (Ta), tantalum nitride (TaN), molybdenum (Mo), ruthenium (Ru), tungsten (W), tungsten nitride (WN), cobalt (Co), aluminum (Al), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), doped polysilicon, or a combination thereof, without being limited thereto.

As shown in FIG. 3, the memory cell block CB of the semiconductor memory device 100 may include a plurality of insulating supporters 110, which pass through the plurality of word line pads WLP in the vertical direction (Z direction). The plurality of insulating supporters 110 may support the plurality of word line pads WLP. In some example embodiments, each of the plurality of insulating supporters 110 may include a silicon oxide film, a silicon nitride film, or a combination thereof. In an example, each of the plurality of insulating supporters 110 may include a silicon oxide plug and a silicon nitride film surrounding a sidewall of the silicon oxide plug. In another example, each of the plurality of insulating supporters 110 may include only the silicon oxide plug. However, a constituent material of the plurality of insulating supporters 110 is not limited to the examples described above.

A gate dielectric film 130 may be between the active region 106A and the word line WL. In some example embodiments, the gate dielectric film 130 may include a paraelectric material. For example, the gate dielectric film 130 may include silicon oxide, silicon nitride, silicon oxynitride, or a combination thereof. In other example embodiments, the gate dielectric film 130 may include a high-k dielectric material. The high-k dielectric material may have a dielectric constant of about 10 to about 25. For example, the high-k dielectric material may include hafnium oxide, aluminum oxide, zirconium oxide, or a combination thereof, without being limited thereto. In still other example embodiments, the gate dielectric film 130 may include a combination of a paraelectric material and a high-k dielectric material.

As shown in FIG. 3, the memory cell block CB of the semiconductor memory device 100 may include a plurality of insulating blocks 149 between the word line pad WLP and the plurality of word lines WL at each of the plurality of vertical levels apart from the substrate 102 in the vertical direction (Z direction). As used herein, from among the plurality of insulating blocks 149, the insulating block 149 located between the first word line pad WLP1 and the plurality of second word lines WL2 may be referred to as a first insulating block. As used herein, from among the plurality of insulating blocks 149, the insulating block 149 located between the second word line pad WLP2 and the plurality of first word lines WL1 may be referred to as a second insulating block. The first word line pad WLP1 may be connected to the plurality of first word lines WL1 and be apart from the second word line WL2 in the second lateral direction (Y direction) with one insulating block 149 (e.g., the first insulating block) therebetween. The second word line pad WLP2 may be connected to the plurality of second word lines WL2 and be apart from the first word line WL1 with one insulating block 149 (e.g., the second insulating block) therebetween in the second lateral direction (Y direction). Each of the plurality of insulating blocks 149 may extend lengthwise in the vertical direction (Z direction) to face, in the second lateral direction (Y direction), the plurality of word line pads WLP, which are arranged in a line in the vertical direction (Z direction). In some example embodiments, each the plurality of insulating blocks 149 may include a silicon oxide film, a silicon nitride film, or a combination thereof.

As shown in FIG. 4, a plurality of active layers 106 may be on a plurality of active regions 106A located at an uppermost vertical level that is farthest from the substrate 102, from among the plurality of active regions 106A. A thickness of each of the plurality of active layers 106 may be greater than a thickness of the active region 106A in the vertical direction (Z direction). In some example embodiments, a plurality of active layers 106 located at the uppermost vertical level may be omitted.

As shown in FIG. 7, a dummy active region D106 and a dummy gate dielectric film D130 surrounding the dummy active region D106 may be inside the insulating block 149. Each of the dummy active region D106 and the dummy gate dielectric film D130 may be at the same vertical level as the plurality of active regions 106A. In some example embodiments, each of the plurality of insulating blocks 149 may include a silicon nitride liner 149A surrounding the dummy active region D106 and the dummy gate dielectric film D130 and a silicon oxide film 149B filling spaces defined by the silicon nitride liner 149A.

The plurality of insulating blocks 149 may include a first silicon oxide liner, a silicon nitride liner, and a silicon oxide film, which are sequentially arranged inward from an outer sidewall of each of the plurality of insulating blocks 149, without being limited thereto.

As shown in FIG. 3, in an end portion of the memory cell block CB in the first lateral direction (X direction), a region between the plurality of active regions 106A and the word line pad WLP and a region defined by a plurality of capacitors CAP, the plurality of active regions 106A, and the word line pad WLP may each be filled by an edge-side insulating structure. The edge-side insulating structure may include a first insulating liner 125, a second insulating liner 126, and a buried insulating film 127, which sequentially cover a surface of each of the plurality of active regions 106A. In some example embodiments, each of the first insulating liner 125 and the buried insulating film 127 may include silicon oxide, and the second insulating liner 126 may include silicon nitride.

As shown in FIGS. 4 and 7, respective spaces between the plurality of word line pads WLP arranged in a line in the vertical direction (Z direction) may be filled by an insulating film 142, and an end portion of each of the plurality of word line pads WLP and the insulating film 142 at an edge side of the memory cell block CB may be covered by an insulating film 146. A space between the plurality of active regions 106A, which are adjacent to the insulating film 142 in the first lateral direction (X direction), and the plurality of word line pads WLP, which are arranged in a line in the vertical direction (Z direction), may be filled by an insulating structure 170. Each of the insulating films 142 and 146 and the insulating structure 170 may include a silicon oxide film, a silicon nitride film, or a combination thereof.

As shown in FIGS. 3 to 6, the memory cell block CB of the semiconductor memory device 100 may include a plurality of bit lines BL extending lengthwise in the vertical direction (Z direction). Each of the plurality of bit lines BL may pass through an insulating structure 129 on the substrate 102 and extend lengthwise in the vertical direction (Z direction). Each of the plurality of bit lines BL may be connected to the plurality of active regions 106 overlapping each other in the vertical direction (Z direction), from among the plurality of active regions 106A included in the memory cell block CB. The insulating structure 129 may include a silicon oxide film, a silicon nitride film, or a combination thereof.

As shown in FIG. 7, respective spaces between the plurality of word lines WL arranged in a line in the vertical direction (Z direction) may be filled by the insulating structure 129.

The plurality of bit lines BL may include a bit line BL connected to a selected one of a plurality of active regions 106A surrounded by the first word line WL1 and a bit line BL connected to a selected one of a plurality of active regions 106A surrounded by the second word line WL2. As used herein, from among the plurality of bit lines BL, a bit line BL connected to the active region 106A surrounded by the first word line WL1 may be referred to as a first bit line, and a bit line BL connected to the active region 106A surrounded by the second word line WL2 may be referred to as a second bit line. The first bit line and the second bit line may be apart from each other in the first lateral direction (X direction) with one first word line WL1, one second word line WL2, a plurality of active regions 106A surrounded by the one first word line WL1, and a plurality of active regions 106A surrounded by the one second word line WL2 therebetween.

In some example embodiments, as shown in FIG. 6, a direct contact DC may be at an end of the first local portion 106S1 of the active region 106A. The direct contact DC, which is a portion of the first local portion 106S1 of the active region 106A, may include a doped silicon layer. For example, the direct contact DC may include a silicon layer doped with an n-type dopant.

In some example embodiments, each of the plurality of bit lines BL may include metal, conductive metal nitride, metal silicide, doped polysilicon, or a combination thereof. For example, each of the plurality of bit lines BL may include Ti, TiN, Ta, TaN, Mo, Ru, W, WN, Co, Al, Ni, TiSi, TiSiN, WSi, WSiN, TaSi, TaSiN, RuTiN, CoSi, NiSi, doped polysilicon, or a combination thereof, without being limited thereto. In other example embodiments, as shown in FIG. 6, each of the plurality of bit lines BL may include a metal silicide film 152, a conductive liner 154, and a conductive plug 156, which are sequentially stacked on a surface of the direct contact DC located at the end of the first local portion 106S1 of the active region 106A. In an X-Y plane, the conductive plug 156 may be surrounded by the conductive liner 154, and the conductive plug 156 and the conductive liner 154 may be surrounded by the metal silicide film 152. In some example embodiments, the metal silicide film 152 may be omitted. In some example embodiments, the metal silicide film 152 may include molybdenum silicide or titanium silicide, the conductive liner 154 may include titanium nitride (TiN), and the conductive plug 156 may include tungsten (W), without being limited thereto.

As shown in FIGS. 3, 5, and 6, the memory cell block CB of the semiconductor memory device 100 may include a plurality of capacitors CAP connected to the plurality of active regions 106A, respectively. Each of the plurality of capacitors CAP may include a first electrode 186, a dielectric film 187, and a second electrode 188. The first electrode 186 of the capacitor CAP may be connected to the second local portion 106S2 of a selected one of the plurality of active regions 106A.

As shown in FIGS. 5 and 6, a metal silicide film 184 may be between the first electrode 186 of the capacitor CAP and the second local portion 106S2 of the active region 106A. The metal silicide film 184 may include molybdenum silicide or titanium silicide, without being limited thereto. The first electrode 186 of the capacitor CAP may be electrically connectable to the second local portion 106S2 of the active region 106A through the metal silicide film 184. In some example embodiments, the metal silicide film 184 may be omitted. In this case, the first electrode 186 of the capacitor CAP may be in contact with the second local portion 106S2 of the active region 106A.

The second electrode 188 of the capacitor CAP may be apart from the active region 106A and cover a surface of the first electrode 186. The dielectric film 187 of the capacitor CAP may be between the first electrode 186 and the second electrode 188. As shown in FIG. 3, the plurality of capacitors CAP may be between the plurality of active regions 106A surrounded by the first word line WL1 and the plurality of active regions 106A surrounded by the second word line WL2.

The plurality of capacitors CAP may be arranged in a line in the second lateral direction (Y direction) between the plurality of active regions 106A surrounded by the first word line WL1 and the plurality of active regions 106A surrounded by the second word line WL2. In addition, in each of the plurality of active regions 106A, the vertical protruding local portion 106G may be between the bit line BL and the capacitor CAP that are adjacent thereto, in the first lateral direction (X direction), and may be more adjacent to the capacitor CAP than the bit line BL.

In each of the plurality of active regions 106A, the first local portion 106S1 may extend in the first lateral direction (X direction) from the vertical protruding local portion 106G toward the bit line BL connected to a corresponding one of the active regions 106A. Each of the plurality of bit lines BL may be in contact with the first local portion 106S1 of a selected one of the plurality of active regions 106A at each of the plurality of vertical levels apart from the substrate 102 in the vertical direction (Z direction). In each of the plurality of active regions 106A, the second local portion 106S2 may extend in the first lateral direction (X direction) from the vertical protruding local portion 106G in a direction away from the bit line BL connected to a corresponding one of the active regions 106A.

In each of the plurality of active regions 106A, the first local portion 106S1 may extend in the first lateral direction (X direction) from the vertical protruding local portion 106G in a direction away from the first electrode 186 of the capacitor CAP. In each of the plurality of active regions 106A, the second local portion 106S2 may extend in the first lateral direction (X direction) from the vertical protruding local portion 106G toward the first electrode 186 of the capacitor CAP.

As shown in FIG. 3, the plurality of capacitors CAP may include a plurality of capacitors CAP, which are connected to the plurality of active regions 106A surrounded by the first word line WL1, respectively, from among the plurality of active regions 106A, and a plurality of capacitors CAP, which are connected to the plurality of active regions 106A surrounded by the second word line WL2, respectively, from among the plurality of active regions 106A. As used herein, from among the plurality of capacitors CAP, the capacitor CAP connected to the active region 106A surrounded by the first word line WL1 may be referred to as a first capacitor, and the capacitor CAP connected to the active region 106A surrounded by the second word line WL2 may be referred to as a second capacitor.

In each of the plurality of capacitors CAP, each of the first electrode 186 and the second electrode 188 may include a metal film, a conductive metal oxide film, a conductive metal nitride film, a conductive metal oxynitride film, or a combination thereof. In some example embodiments, each of the first electrode 186 and the second electrode 188 may include titanium (Ti), Ti nitride, Ti oxide, Ti oxynitride, niobium (Nb), Nb nitride, Nb oxide, Nb oxynitride, cobalt (Co), Co nitride, Co oxide, Co oxynitride, tin (Sn), Sn nitride, Sn oxide, Sn oxynitride, or a combination thereof. For example, each of the first electrode 186 and the second electrode 188 may include TiN, NbN, CON, SnO₂, or a combination thereof. In other example embodiments, each of the first electrode 186 and the second electrode 188 may include TaN, TiAlN, TaAlN, V, VN, Mo, MON, W, WN, Ru, RuO₂, SrRuO₃, Ir, IrO₂, Pt, PtO, SRO (SrRuO₃), BSRO((Ba,Sr)RuO₃), CRO(CaRuO₃), LSCO((La,Sr)CoO₃), or a combination thereof. However, a constituent material of each of the first electrode 186 and the second electrode 188 is not limited to the examples described above. The dielectric film 187 may include a silicon oxide film, a high-k dielectric film, or a combination thereof. In some example embodiments, the dielectric film 187 may include metal oxide including at least metal selected from hafnium (Hf), zirconium (Zr), aluminum (Al), niobium (Nb), cerium (Ce), lanthanum (La), tantalum (Ta), and titanium (Ti). In some example embodiments, the dielectric film 187 may have a single film structure including one high-k dielectric film. In other example embodiments, the dielectric film 187 may have a multilayered film structure including a plurality of high-k dielectric films sequentially stacked on the first electrode 186. The high-k dielectric film may be selected from a HfO₂ film, a ZrO₂ film, an Al₂O₃ film, a La₂O₃ film, a Ta₂O₃ film, a Nb₂O₅ film, a CeO₂ film, a TiO₂ film, and a GeO₂ film, without being limited thereto. In other example embodiments, the dielectric film 187 may include oxide of at least one metal selected from Ti, Nb, Ta, Sn, and Mo or oxynitride of at least one metal selected from Ti, Nb, Ta, Sn, and Mo. For example, the dielectric film 187 may include Ti oxide, Ti oxynitride, Nb oxide, Nb oxynitride, Ta oxide, Ta oxynitride, Sn oxide, Sn oxynitride, Mo oxide, Mo oxynitride, or a combination thereof. In still other example embodiments, the dielectric film 187 may include a ferroelectric film including an oxide of at least one selected from hafnium (Hf), silicon (Si), aluminum (Al), zirconium (Zr), yttrium (Y), lanthanum (La), gadolinium (Gd), and strontium (Sr). The ferroelectric film may include a hafnium-based oxide, for example, hafnium oxide (HfO), hafnium zirconium oxide (HZO), hafnium titanium oxide, or hafnium silicon oxide. The ferroelectric film may further include a dopant as needed. The dopant may include at least one element selected from silicon (Si), aluminum (Al), zirconium (Zr), yttrium (Y), lanthanum (La), gadolinium (Gd), scandium (Sc), strontium (Sr), magnesium (Mg), and barium (Ba), without being limited thereto.

As shown in FIGS. 3, 5, and 6, the memory cell block CB of the semiconductor memory device 100 may further include a plate electrode 190. The plate electrode 190 may correspond to the plate electrode PL described with reference to FIG. 1. As shown in FIG. 5, the plate electrode 190 may include a center portion 190A extending lengthwise on the substrate 102 in the vertical direction (Z direction) and a plurality of finger portions 190B protruding from the center portion 190A in the first lateral direction (X direction). Each of the plurality of finger portions 190B of the plate electrode 190 may overlap the first electrode 186 of the capacitor CAP in the vertical direction (Z direction). The plurality of finger portions 190B of the plate electrode 190 may be apart from the first electrode 186 of the capacitor CAP with the dielectric film 187 and the second electrode 188 of the capacitor CAP therebetween and may extend in the vertical direction (Z direction).

The plate electrode 190 may be between a plurality of active regions 106A (e.g., a plurality of first active regions), which are surrounded by the first word line WL1, and a plurality of active regions 106A (e.g., a plurality of second active regions), which are surrounded by the second word line WL2, in the first lateral direction (X direction). The plate electrode 190 may be between a capacitor CAP (e.g., the first capacitor), which is connected to the active region 106A surrounded by the first word line WL1, and a capacitor CAP (e.g., the second capacitor), which is connected to the active region 106A surrounded by the second word line WL2, in the first lateral direction (X direction).

The plate electrode 190 may be connected to the capacitor CAP connected to the active region 106A surrounded by the first word line WL1 and also be connected to the capacitor CAP connected to the active region 106A surrounded by the second word line WL2. One plate electrode 190 may be shared by a plurality of capacitors CAP, each of which is connected to the active region 106A surrounded by the first word line WL1, and a plurality of capacitors CAP, each of which is connected to the active region 106A surrounded by the second word line WL2. As shown in FIG. 5, from among the plurality of active regions 106A, the plurality of active regions 106A surrounded by the first word line WL1 may have symmetrical cross-sectional shapes with the plurality of active regions 106A surrounded by the second word line WL2 about a central axis of the plate electrode 190 in the vertical direction (Z direction).

The plate electrode 190 may include a metal film, a conductive metal oxide film, a conductive metal nitride film, a conductive metal oxynitride film, a semiconductor film, or a combination thereof. In some example embodiments, the plate electrode 190 may include Ti, Ti nitride, Ti oxide, Ti oxynitride, Nb, Nb nitride, Nb oxide, Nb oxynitride, Co, Co nitride, Co oxide, Co oxynitride, Sn, Sn nitride, Sn oxide, Sn oxynitride, SiGe, or a combination thereof. For example, the plate electrode 190 may include titanium nitride (TiN), niobium nitride (NbN), tantalum nitride (TaN), titanium aluminum nitride (TiAlN), tantalum aluminum nitride (TaAlN), vanadium (V), vanadium nitride (VN), molybdenum (Mo), molybdenum nitride (MoN), tungsten (W), tungsten nitride (WN), ruthenium (Ru), iridium (Ir), platinum (Pt), silicon germanium (SiGe), or a combination thereof, without being limited thereto.

As shown in FIG. 6, a surface of each of the active region 106A, the gate dielectric film 130, the word line WL, and the insulating structure 129 may be covered by a third insulating liner 172 between the capacitor CAP and the word line WL, and a region defined by the third insulating liner 172 and the dielectric film 187 of the capacitor CAP may be filled by a buried insulating film 173. The third insulating liner 172 and the buried insulating film 173 may constitute an insulating structure 170. In some example embodiments, the third insulating liner 172 may include silicon oxide, and the buried insulating film 173 may include silicon nitride, without being limited thereto.

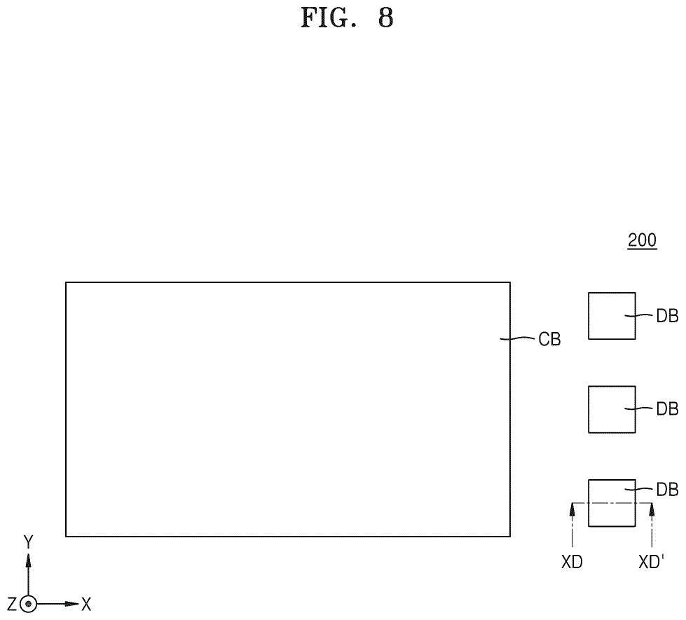

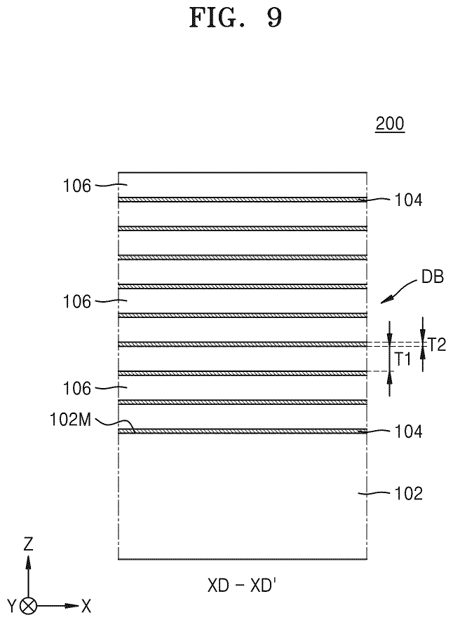

FIG. 8 is a plan view of a semiconductor memory device 200 according to an example embodiment. FIG. 9 is a cross-sectional view taken along line XD-XD′ of FIG. 8.

Referring to FIGS. 8 and 9, the semiconductor memory device 200 may include a memory cell block CB and a plurality of dummy blocks DB located around the memory cell block CB. The memory cell block CB may have the same configuration as described with reference to FIGS. 2 to 7. When a chemical mechanical polishing (CMP) process is performed during the manufacture of the memory cell block CB, the plurality of dummy blocks DB may mitigate or prevent the occurrence of problems (e.g., a dishing phenomenon) due to pattern density non-uniformity in a surrounding area of the memory cell block CB where pattern density is relatively low.

As shown in FIG. 9, each of the plurality of dummy blocks DB may include a plurality of sacrificial layers 104 and a plurality of active layers 106, which are alternately stacked one-by-one on a main surface 102M of a substrate 102 in a vertical direction (Z direction). In some example embodiments, each of the plurality of sacrificial layers 104 and the plurality of active layers 106 may include a semiconductor material. However, a first semiconductor material included in the plurality of sacrificial layers 104 may be different from a second semiconductor material included in the plurality of active layers 106. In some example embodiments, in the plurality of dummy blocks DB, each of the plurality of sacrificial layers 104 may include an undoped SiGe layer or a SiGe layer doped with carbon (C) atoms, and each of the plurality of active layers 106 may include a Si layer. In the vertical direction (Z direction), a thickness T1 of each of the plurality of active layers 106 may be greater than a thickness T2 of each of the plurality of sacrificial layers 104. In some example embodiments, the thickness T1 of each of the plurality of active layers 106 may be at least three times greater than the thickness T2 of each of the plurality of sacrificial layers 104, without being limited thereto.

Each of the semiconductor memory devices 100 and 200 described with reference to FIGS. 1 to 9 may include the memory cell block CB with a three-dimensional (3D) structure including a plurality of memory cells, which are repeatedly arranged on the substrate 102 in a first lateral direction (X direction), a second lateral direction (Y direction), and the vertical direction (Z direction). The memory cell block CB may include a plurality of word lines WL repeatedly arranged in the first lateral direction (X direction) on a plane on the substrate 102 and a pair of word line pads WLP apart from each other in the second lateral direction (Y direction) with the plurality of word lines WL therebetween. From among the plurality of word lines WL, some word lines WL may be connected to a selected one of the pair of word line pads WLP, and some other word lines WL may be connected to another selected one of the pair of word line pads WLP. By adopting the above-described configuration, the plurality of memory cells may be effectively arranged to reduce or minimize an area occupied by the plurality of memory cells in the memory cell block CB. As compared to a structure of a typical semiconductor memory device, the number of word line pads WLP and an area occupied by the word line pad WLP may be markedly reduced in the memory cell block CB. Therefore, according to the memory cell block CB with the 3D structure, the performance of a semiconductor memory device may improve without inefficiently increasing the area occupied by the plurality of memory cells, and a structure advantageous for high integration may be provided.

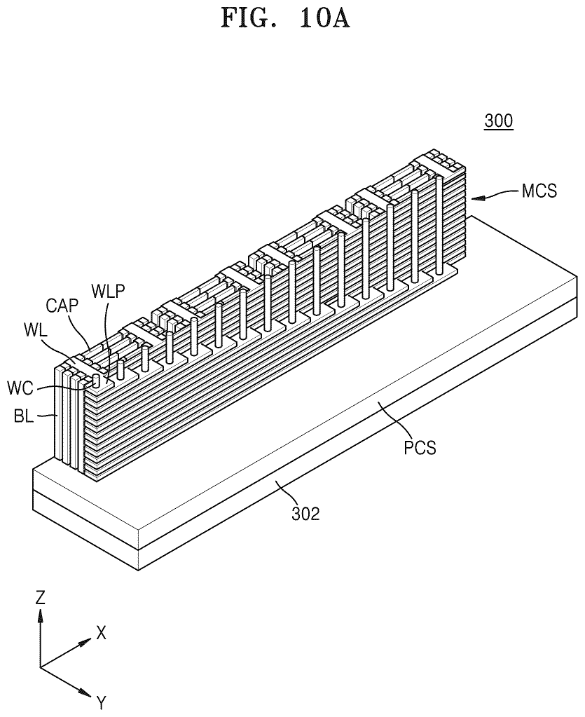

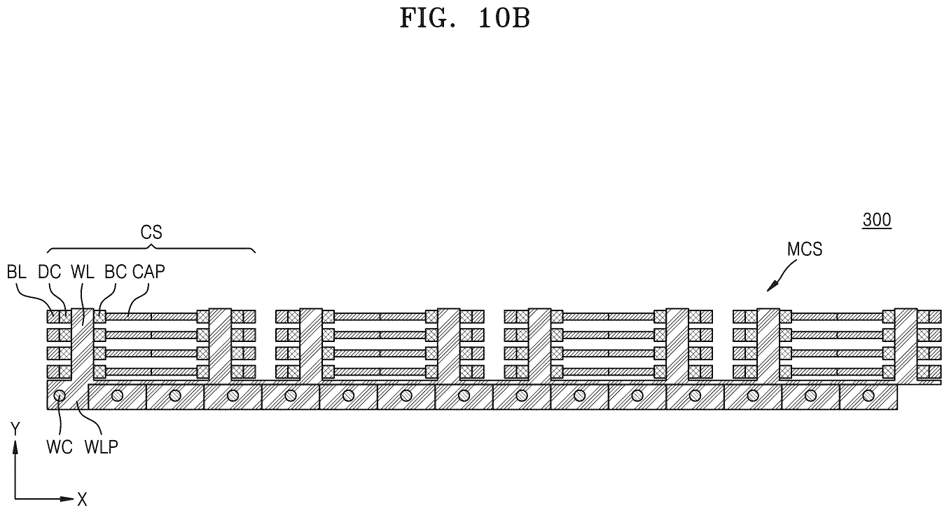

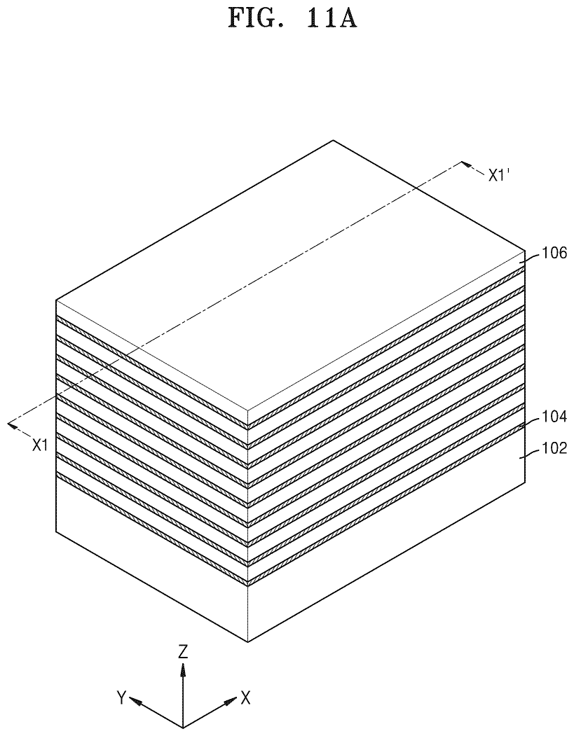

FIG. 10A is a perspective view of a partial region of a semiconductor memory device 300 according to an example embodiment. FIG. 10B is a plan view of a partial region of the semiconductor memory device 300 shown in FIG. 10A. FIGS. 10A and 10B illustrate some components of a cell array structure MCS of the semiconductor memory device 300.

Referring to FIGS. 10A and 10B, the semiconductor memory device 300 may include a substrate 302, and a peripheral circuit structure PCS and the cell array structure MCS, which are on the substrate 302. The cell array structure MCS may be apart from the substrate 302 with the peripheral circuit structure PCS therebetween in a vertical direction (Z direction), and the peripheral circuit structure PCS may overlap the cell array structure MCS in the vertical direction (Z direction).

The substrate 302 may include a semiconductor element (e.g., Si and Ge) or a compound semiconductor (e.g., silicon carbide (SiC), gallium arsenide (GaAs), indium arsenide (InAs), and indium phosphide (InP)). The substrate 302 may include a semiconductor substrate, at least one insulating film formed on the semiconductor substrate, or structures including at least one conductive region. The conductive region may include, for example, a doped well or a doped structure. In some example embodiments, the substrate 302 may have various device isolation structures, such as a shallow trench isolation (STI) structure.

The peripheral circuit structure PCS may include peripheral circuit transistors located on the substrate 302 and a peripheral circuit wiring structure configured to connect the peripheral circuit transistors to each other or connect the peripheral circuit transistors to components of the cell array structure MCS. The peripheral circuit transistor may constitute a plurality of peripheral circuits. The plurality of peripheral circuits, which include the peripheral circuit transistor, may include various circuits described with reference to FIG. 1. For example, the plurality of peripheral circuits may include the command decoder 12, the address buffer 13, the address decoder 14, the control circuit 15, the sense amplifier 16, and the data I/O circuit 17, which are shown in FIG. 1.

The cell array structure MCS may include a plurality of stack structures CS. Each of the plurality of stack structures CS may include a plurality of word lines WL, a plurality of bit lines BL, and a plurality of capacitors CAP. The plurality of stack structures CS may be apart from each other in a first lateral direction (X direction) on the peripheral circuit structure PCS. FIGS. 10A and 10B each illustrate a configuration of the stack structure CS including the plurality of word lines WL, the plurality of bit lines BL, and the plurality of capacitors CAP, the stack structure CS may have the same configuration as the memory cell block CB described above with reference to FIGS. 2 to 7. A buried contact BC may be between the word line WL and the capacitor CAP, and a direct contact DC may be between the word line WL and the bit line BL. Each of the buried contact BC and the direct contact DC may be a portion of the active region 106A described with reference to FIGS. 2 to 7.

A word line pad WLP may be connected to one side of each of the plurality of word lines WL. Word line pads WLP may overlap each other in the vertical direction (Z direction. From among the plurality of word lines WL included in each of the plurality of stack structures CS, some of the plurality of word lines WL arranged at an arbitrary vertical level (hereinafter, a first vertical level) that is apart from the substrate 302 in the vertical direction (Z direction) may be connected to one word line pad WLP arranged at the first vertical level. Some others of the plurality of word lines WL arranged at the first vertical level may be connected to another word line pad WLP arranged at the first vertical level.

A plurality of word line pads WLP arranged on the substrate 302 may have a width in the first lateral direction (X direction), which gradually reduces away from the substrate 302 in the vertical direction (Z direction). Accordingly, the plurality of word line pads WLP may be provided in a staircase form.

A plurality of word line contacts WC may be respectively on the plurality of word line pads WLP. The word line contact WC may be connected to the word lines WL located at the same vertical level, from among the plurality of word lines WL included in each of the plurality of stack structures CS.

According to the semiconductor memory device 300, from among the plurality of word lines WL included in each of the plurality of stack structures CS, the plurality of word lines WL located at the same vertical level may be connected to the word line contact WC through the word line pad WLP that is located at the same vertical level as the plurality of word lines WL located at the same vertical level. Thus, there may be no need to individually form a word line for each of the plurality of word lines WL located at the same vertical level, from among the plurality of word lines WL included in each of the plurality of stack structures CS. Accordingly, a space for forming the word line contact WC may be reduced. Therefore, a relatively large number of memory cells may be arranged in the same area. Thus, the integration density of the semiconductor memory device 300 may improve.

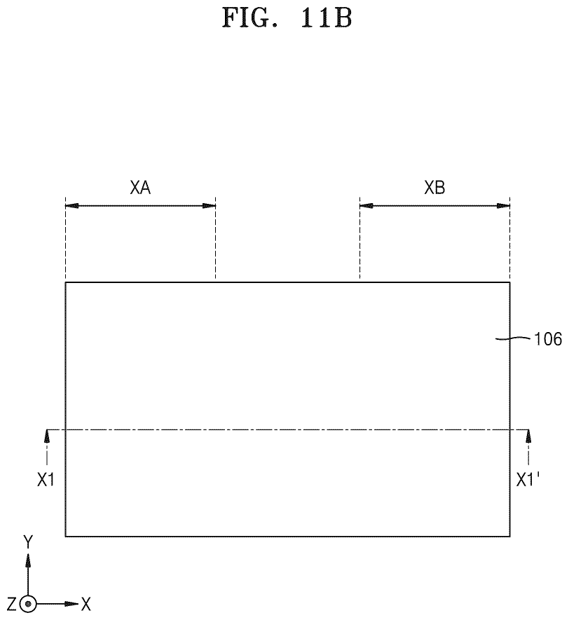

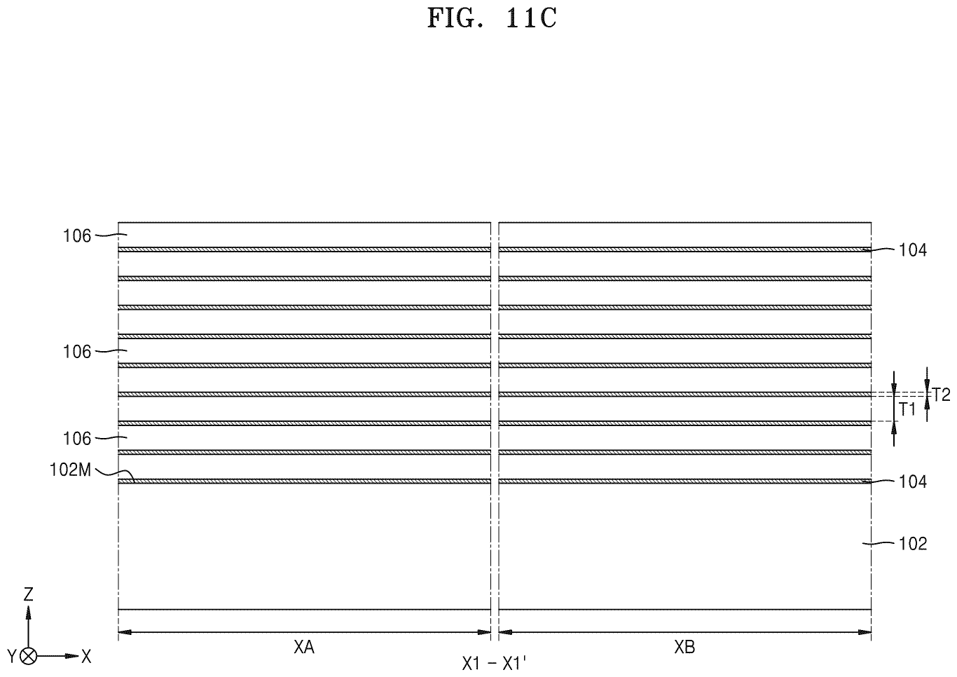

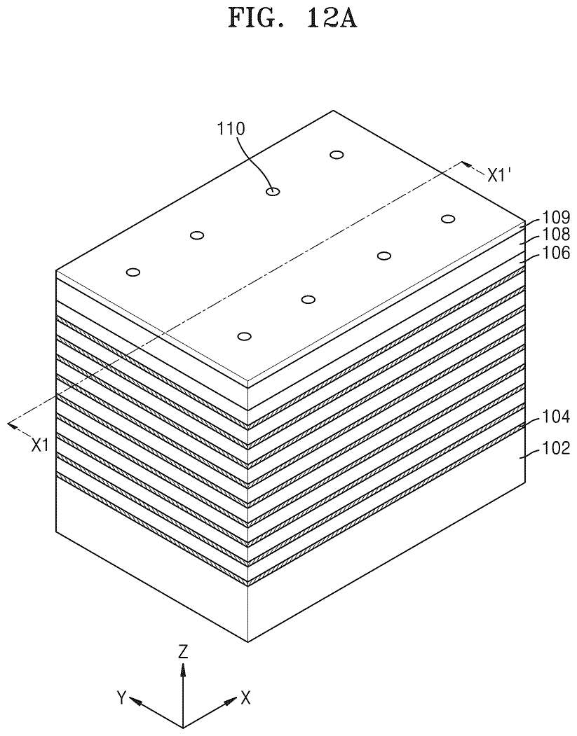

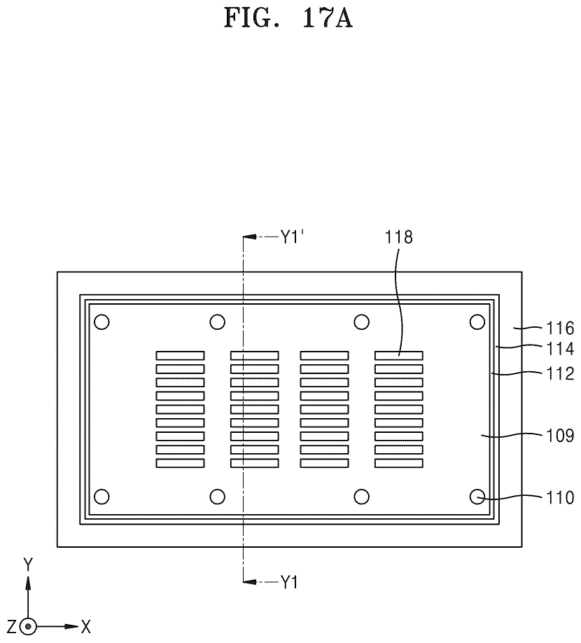

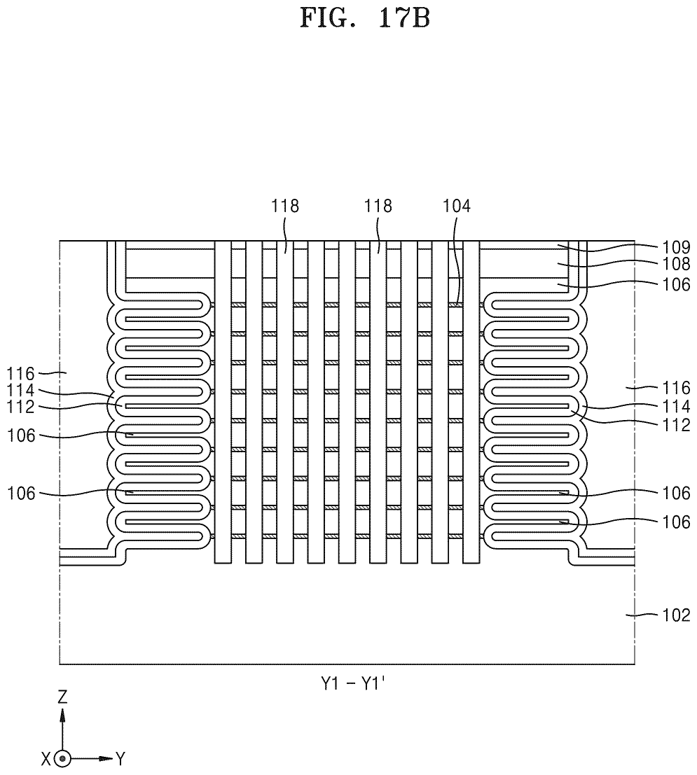

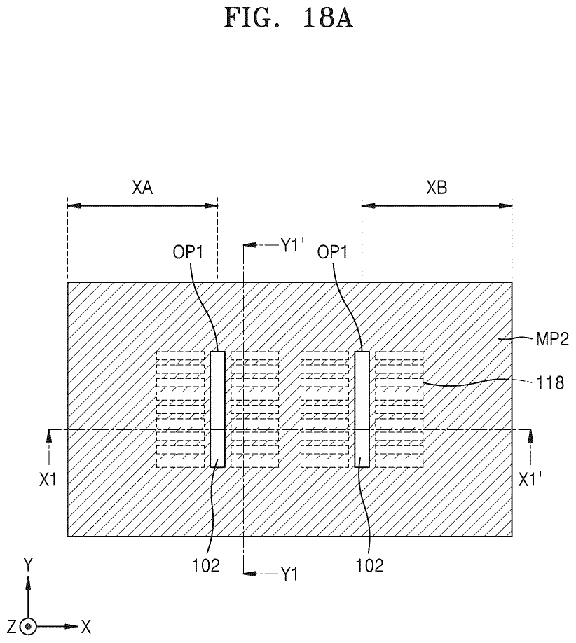

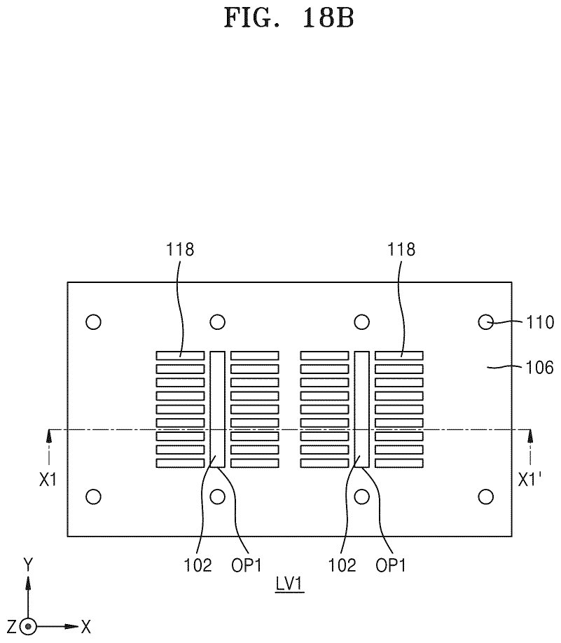

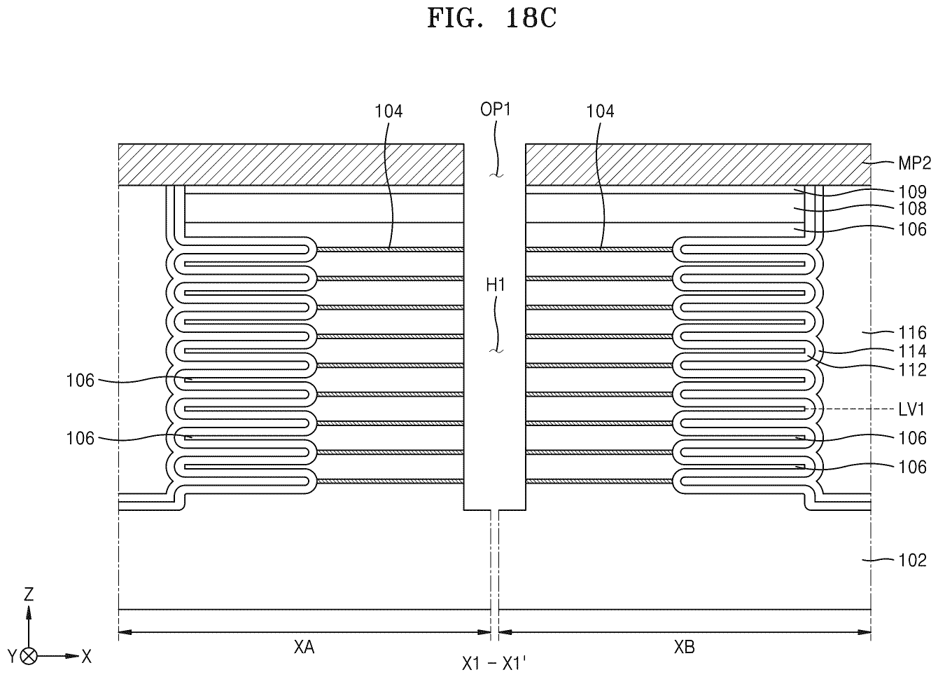

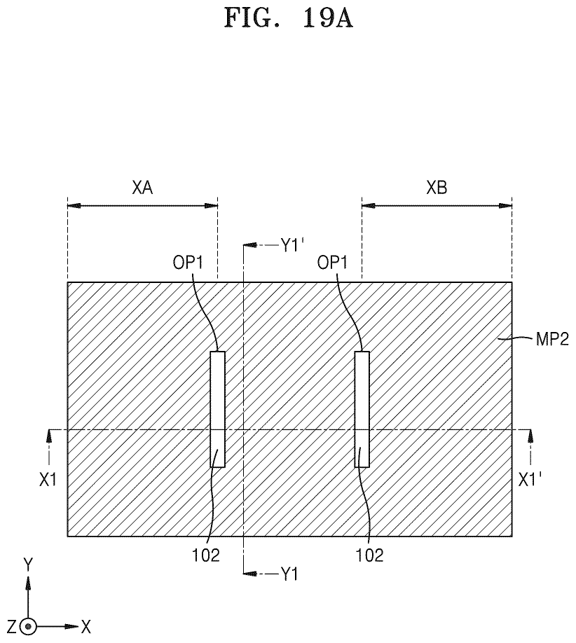

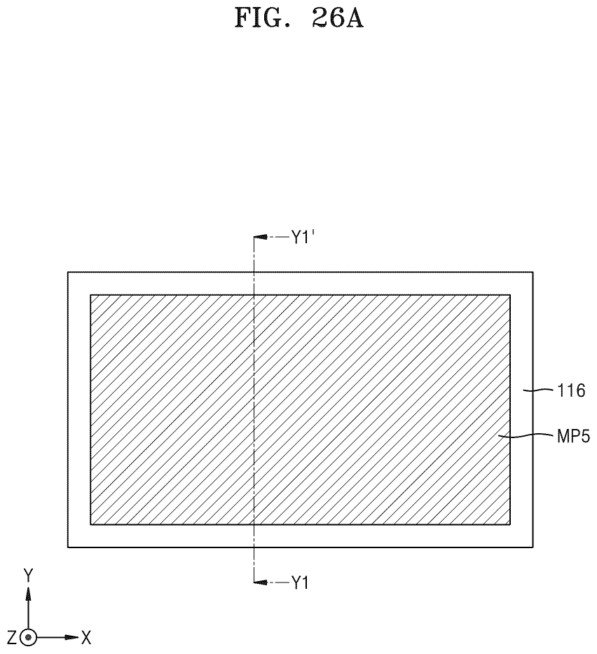

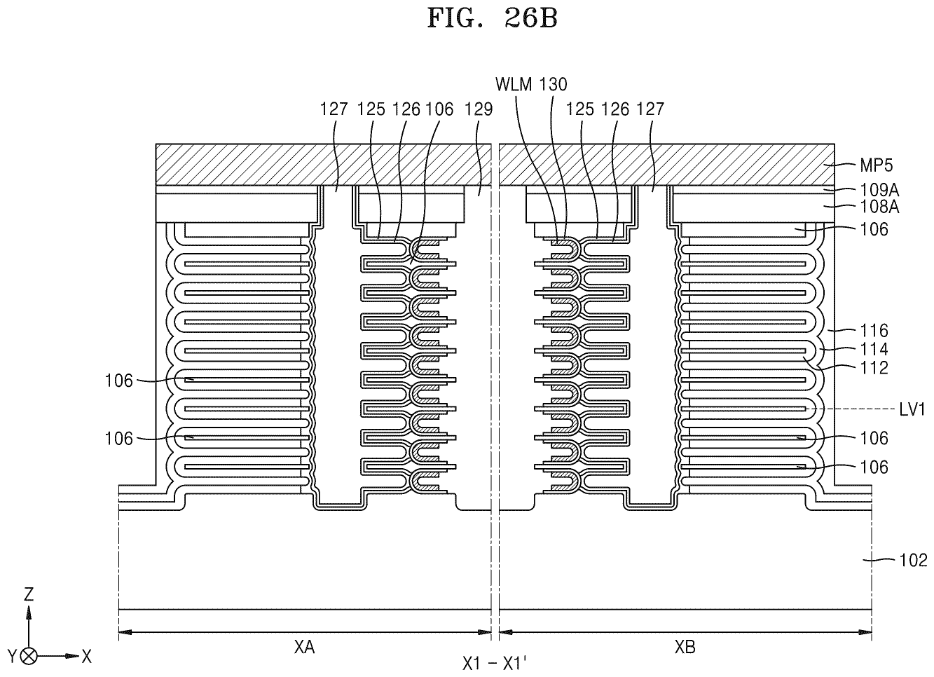

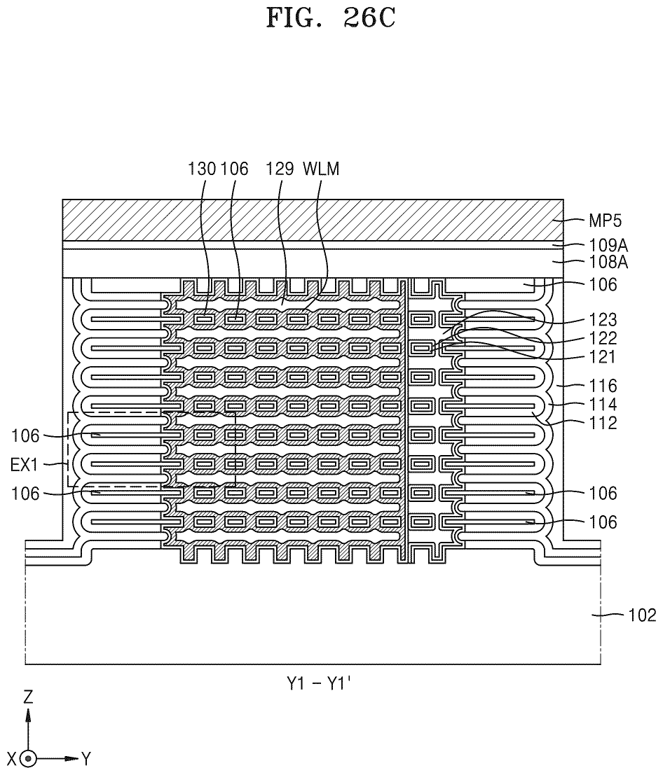

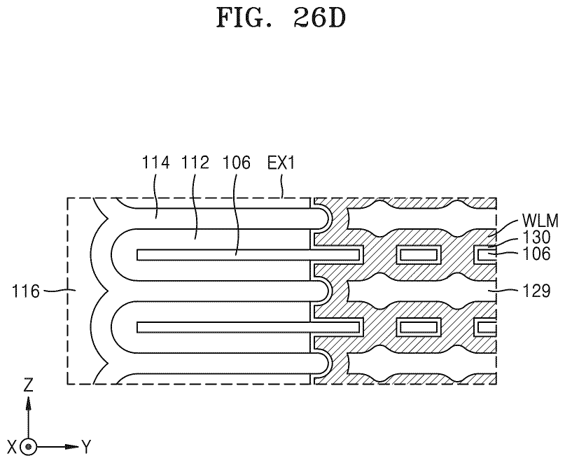

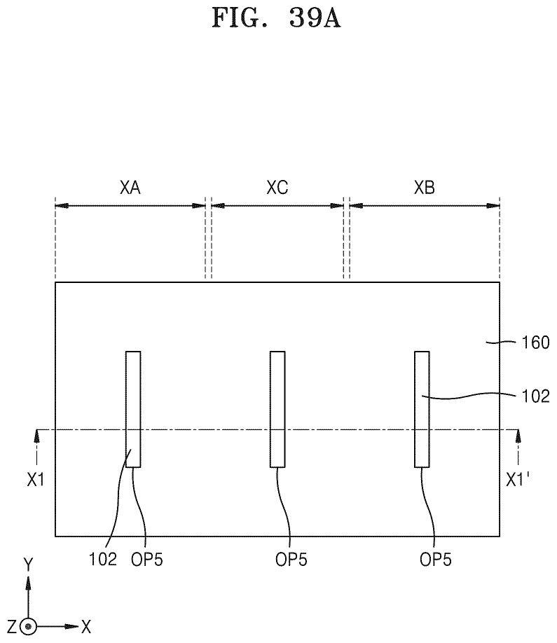

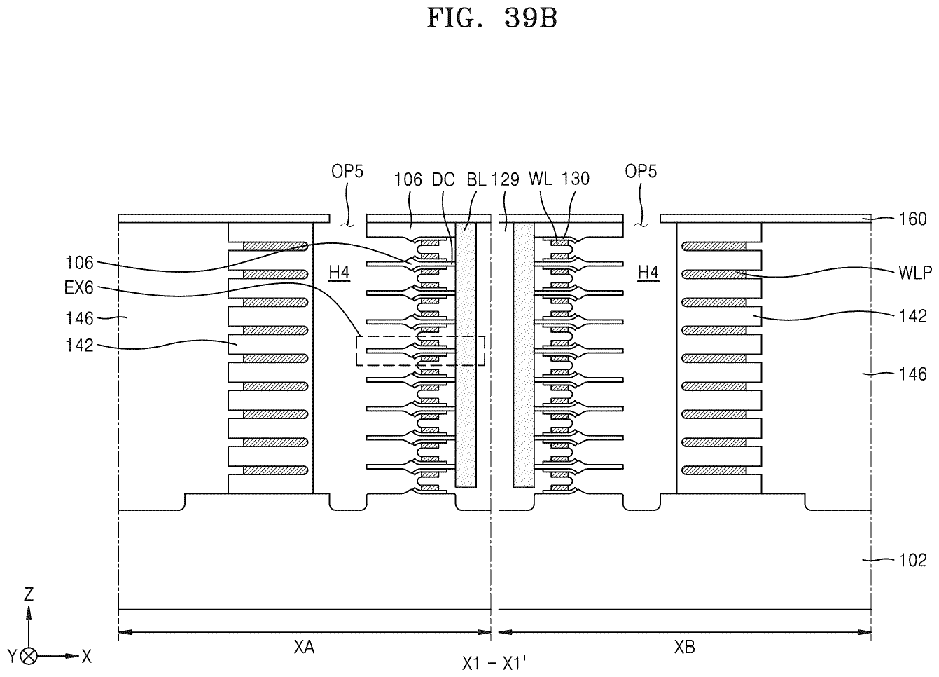

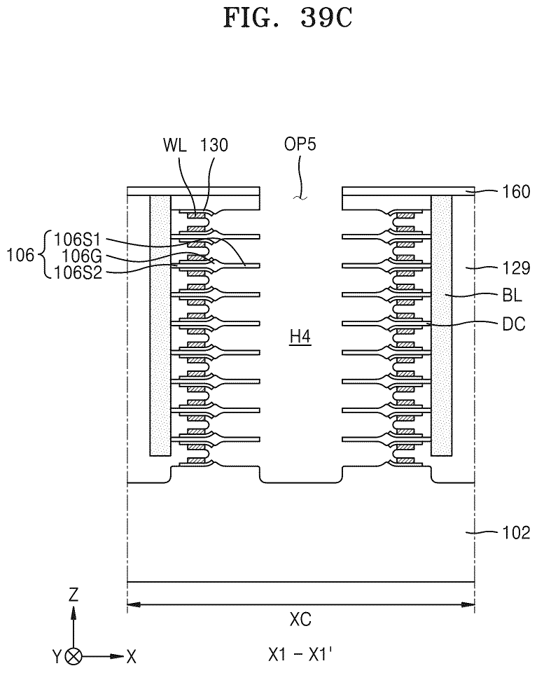

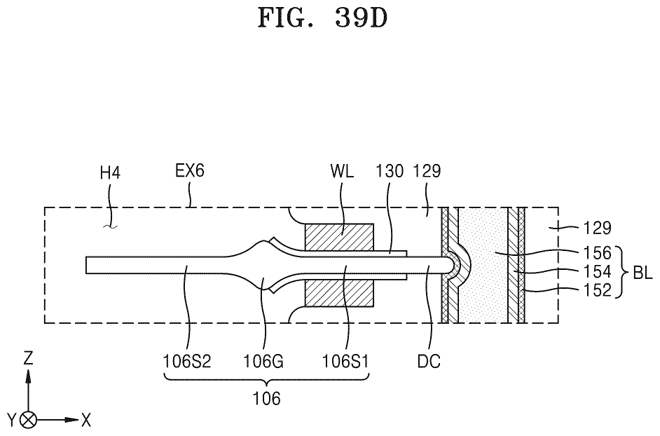

FIGS. 11A to 47C are diagrams illustrating a method of manufacturing a semiconductor memory device, according to an example embodiment. More specifically, FIGS. 11A, 12A, 13A, and 16A are perspective views of a process sequence of a method of manufacturing a semiconductor memory device. FIGS. 11B, 17A, 18A, 19A, 21A, 23A, 26A, 37A, 39A, 40A, and 41A are plan views of a process sequence of a method of manufacturing a semiconductor memory device. FIGS. 18B, 19B, 20A, 21B, 22A, 25A, 36A, 37B, 38A, 41B, and 47A are plan views of a partial region on a plane (X-Y plane) at the first vertical level LV1 shown in FIG. 4. FIGS. 11C, 12B, 13B, 14, 15, 16B, 18C, 19C, 20B, 21C, 22B, 23B, 24A, 25B, 26B, 36B, 38B, 39B, and 40B are cross-sectional views of partial regions of the first region XA and the second region XB of FIG. 2, which correspond to a cross-section taken along line X1-X1′ of FIG. 2, according to a process sequence. FIGS. 39C, 40C, 41C, and 47B are cross-sectional views of a partial region of the third region XC of FIG. 2, which corresponds to a cross-section taken along line X1-X1′ of FIG. 2, according to a process sequence. FIGS. 17B, 19D, 20C, 23C, 24B, 25C, 26C, 29A, 30A, 31, 36C, and 37C are cross-sectional views of a partial region corresponding to a cross-section taken along line Y1-Y1′ of FIG. 2, according to a process sequence. FIGS. 26D, 27, 28, 29B, 30B, 32, 33, 34, 35, 38C, 39D, 41D, 42, 43, 44, 45, 46, and 47C are enlarged cross-sectional views of partial regions of the first region XA and the second region XB of FIG. 2, which correspond to a cross-section X1-X1′ or a cross-section Y1-Y1′ of FIG. 2, according to a process sequence. A method of manufacturing the semiconductor memory device 100 shown in FIGS. 2 to 7 is described with reference to FIGS. 11A to 47C. In FIGS. 11A to 47C, the same reference numerals are used to denote the same elements as in FIGS. 2 to 7, and thus, repeated descriptions thereof are omitted.

Referring to FIGS. 11A, 11B, and 11C, a plurality of sacrificial layers 104 and a plurality of active layers 106 may be alternately stacked one-by-one on a main surface 102M of a substrate 102 in a vertical direction (Z direction). In some example embodiments, each of the plurality of sacrificial layers 104 and the plurality of active layers 106 may include a semiconductor material. In some example embodiments, each of the plurality of sacrificial layers 104 may include an undoped SiGe layer or a SiGe layer doped with carbon (C) atoms, and each of the plurality of active layers 106 may include a Si layer. In the vertical direction (Z direction), a thickness T1 of each of the plurality of active layers 106 may be greater than a thickness T2 of each of the plurality of sacrificial layers 104. In some example embodiments, the thickness T1 of each of the plurality of active layers 106 may be at least three times greater than the thickness T2 of each of the plurality of sacrificial layers 104, without being limited thereto.

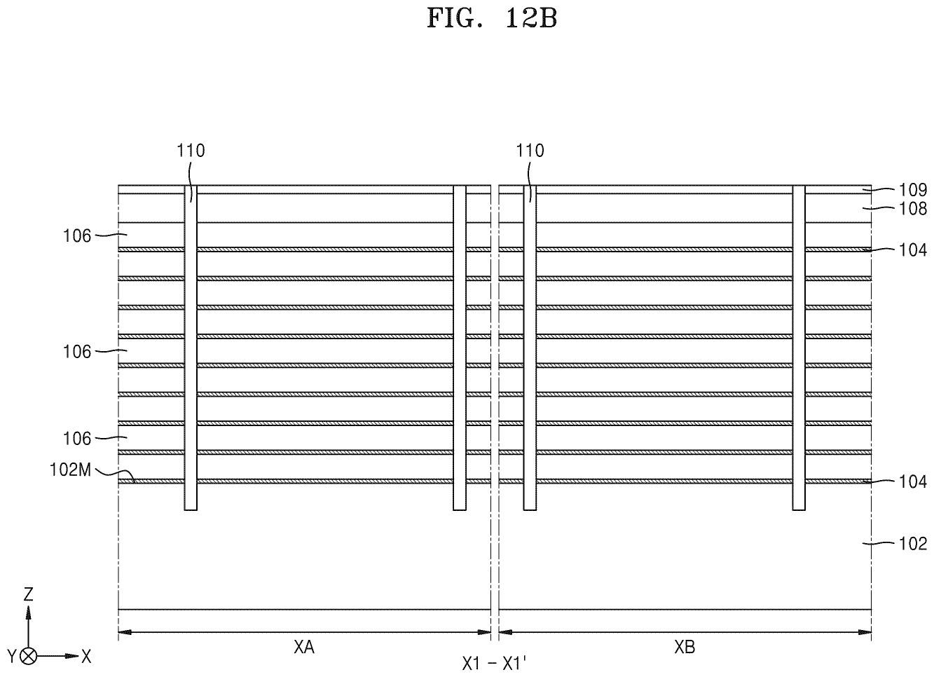

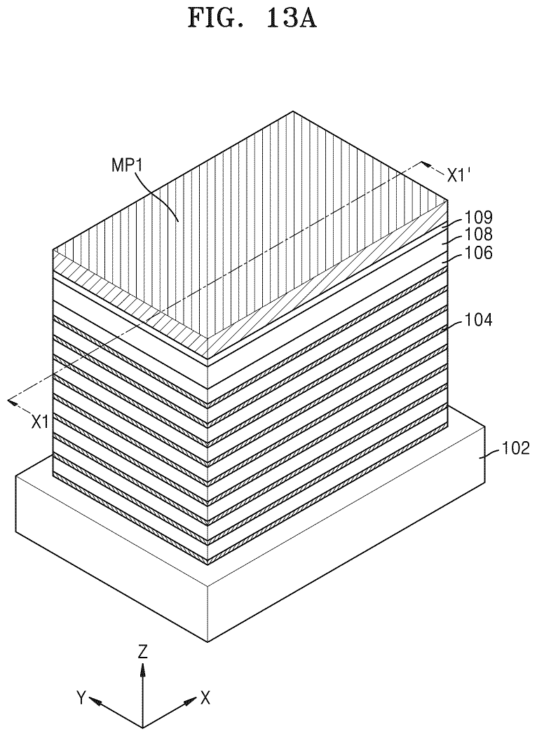

Referring to FIGS. 12A and 12B, a silicon oxide film 108 and a silicon nitride film 109 may be sequentially formed on a stack structure including the plurality of sacrificial layers 104 and the plurality of active layers 106. A plurality of vertical holes may be formed by using a photolithography process to pass through a partial region of the stack structure in the vertical direction (Z direction). The plurality of vertical holes may be filled by an insulating material to form a plurality of insulating supporters 110.

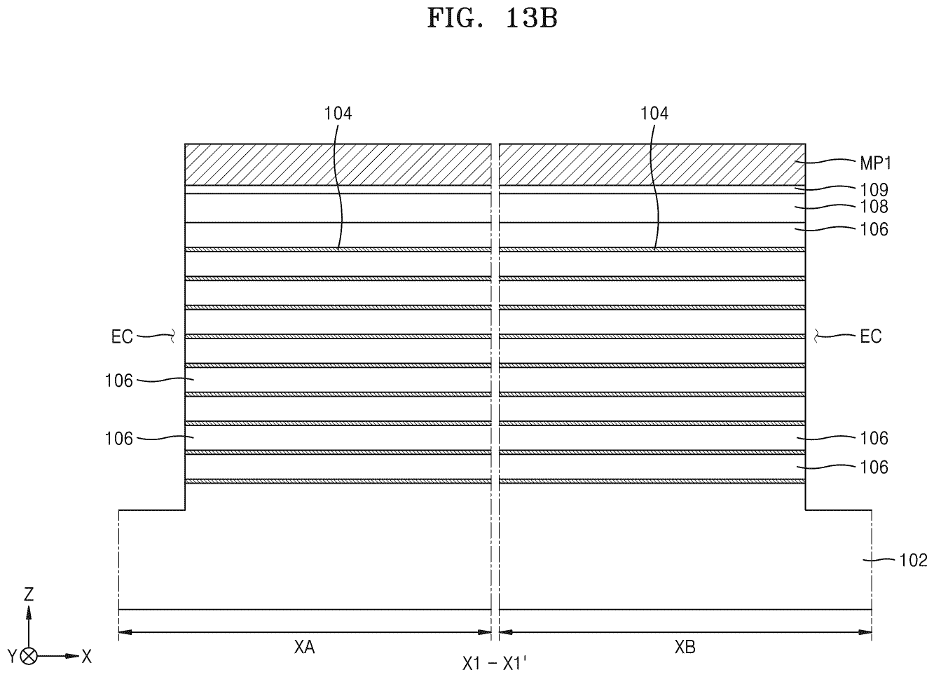

Referring to FIGS. 13A and 13B, in the resultant structure of FIGS. 12A and 12B, a mask pattern MP1 may be formed on the silicon nitride film 109, a partial region of each of the silicon nitride film 109, the silicon oxide film 108, the plurality of sacrificial layers 104, and the plurality of active layers 106 may be etched by using the mask pattern MP1 as an etch mask, and thus, the stack structure including the plurality of sacrificial layers 104 and the plurality of active layers 106 may have a desired planar size. Thus, an edge cut space EC exposing the substrate 102 may be provided around the stack structure including the plurality of sacrificial layers 104 and the plurality of active layers 106.

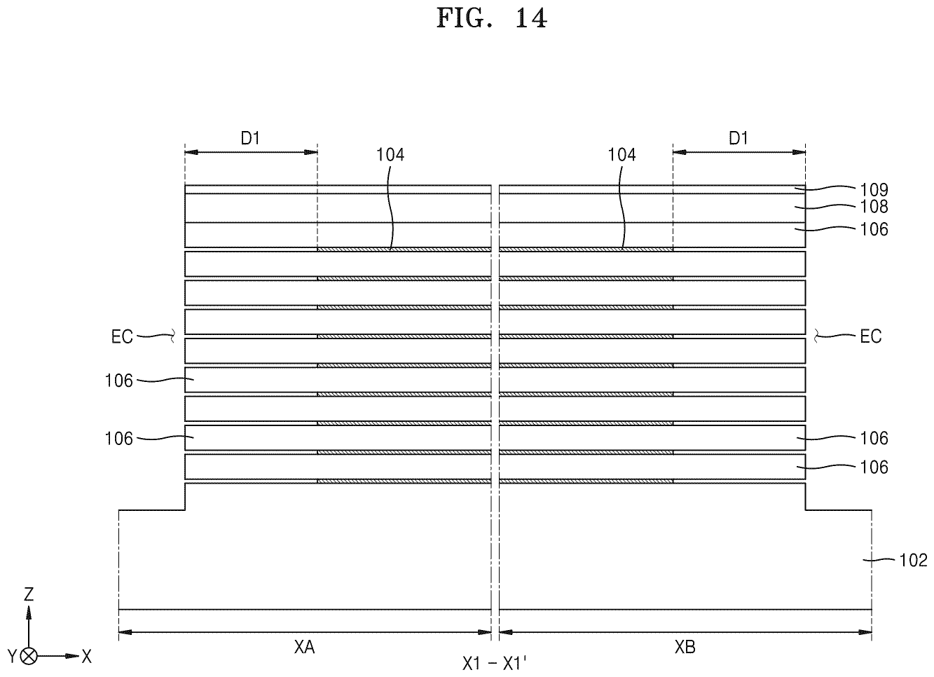

Referring to FIG. 14, in the resultant structure of FIGS. 13A and 13B, portions of the plurality of sacrificial layers 104 may be removed a first lateral distance D1 by using a wet etching process through the edge cut space EC exposing both sidewalls of the stack structure including the plurality of sacrificial layers 104 and the plurality of active layers 106 in each of a first lateral direction (X direction) and a second lateral direction (Y direction). The first lateral distance D1 may correspond to a position at which the plurality of word line pads WLP shown in FIG. 4 are to be formed. In this case, a width of each of the plurality of active layers 106 in a lateral direction may also be reduced to a small extent.

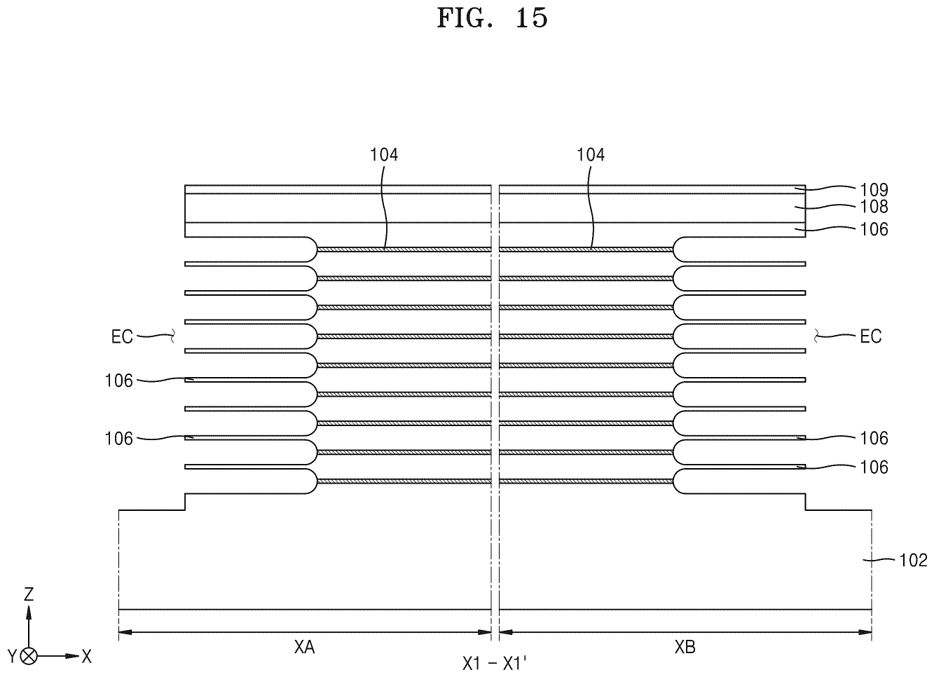

Referring to FIG. 15, each of the plurality of active layers 106 may be removed by a partial thickness through spaces where the portions of the plurality of sacrificial layers 104 are removed from the resultant structure of FIG. 14. Thus, a thickness of the active layer 106 in the vertical direction (Z direction) may be reduced in a partial region of each of the plurality of active layers 106.

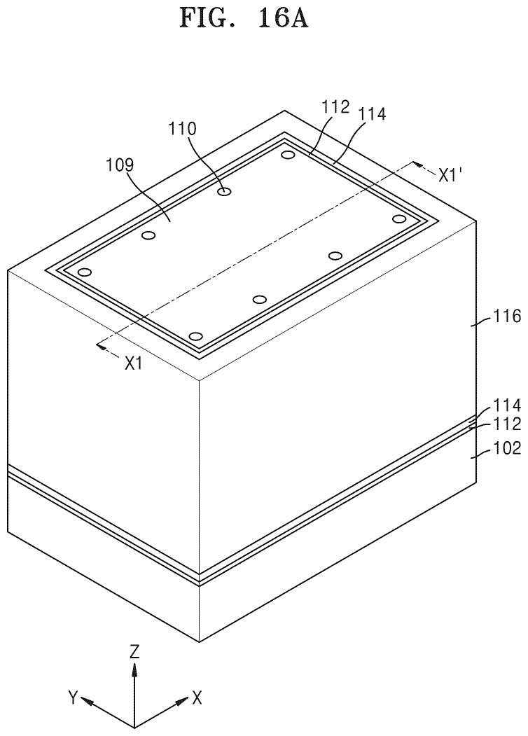

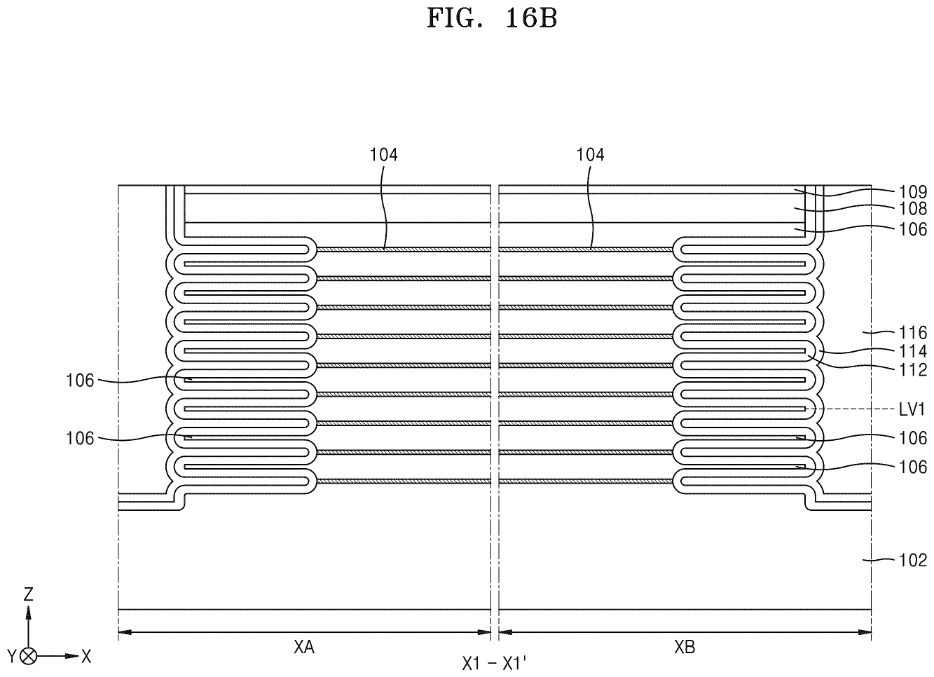

Referring to FIGS. 16A and 16B, a first insulating liner 112 and a second insulating liner 114 may be formed to conformally cover exposed surfaces in the resultant structure of FIG. 15, and a space above the second insulating liner 114 may be filled by a buried insulating film 116. In some example embodiments, the first insulating liner 112 may include silicon oxide, the second insulating liner 114 may include silicon nitride, and the buried insulating film 116 may include silicon oxide.

Referring to FIGS. 17A and 17B, in the resultant structure of FIGS. 16A and 16B, partial regions of the stack structure including the plurality of sacrificial layers 104 and the plurality of active layers 106 may be etched to form a plurality of openings exposing the substrate 102. The plurality of openings may be filled by an insulating film through respective entrances of the plurality of openings exposed at a top surface of the silicon nitride film 109. Thereafter, in the resultant structure, undesirable materials remaining on the silicon nitride film 109 may be polished by using a CMP process so that the top surface of the silicon nitride film 109 may be exposed. Thus, a plurality of insulating plugs 118 may be formed to fill the plurality of openings. Each of the plurality of insulating plugs 118 may include silicon oxide.

Referring to FIGS. 18A, 18B, and 18C, a mask pattern MP2 may be formed on the resultant structure of FIGS. 17A and 17B. The mask pattern MP2 may include a plurality of first openings OP1. For brevity, the plurality of insulating plugs 118 under the mask pattern MP2 are illustrated with dashed lines in FIG. 18A. The stack structure including the plurality of sacrificial layers 104 and the plurality of active layers 106 may be etched through the plurality of first openings OP1 by using the mask pattern MP2 as an etch mask, and thus, a plurality of holes H1 exposing the substrate 102 may be formed in the stack structure.

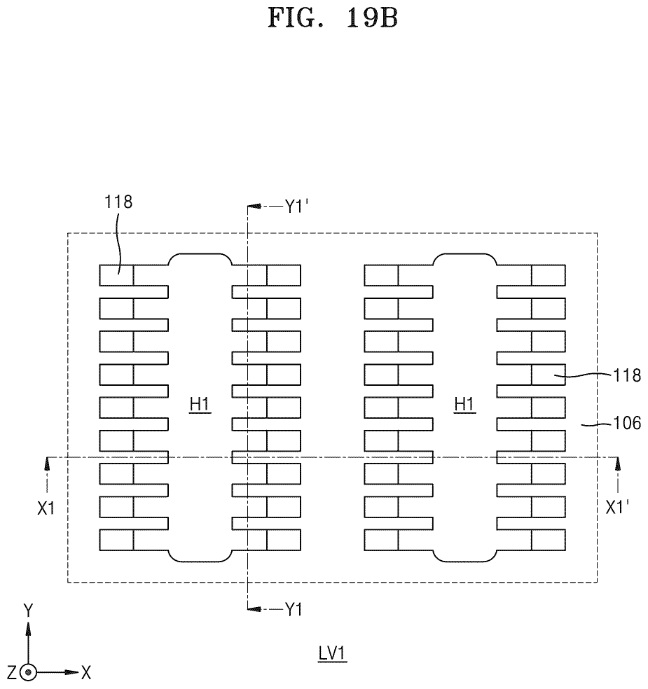

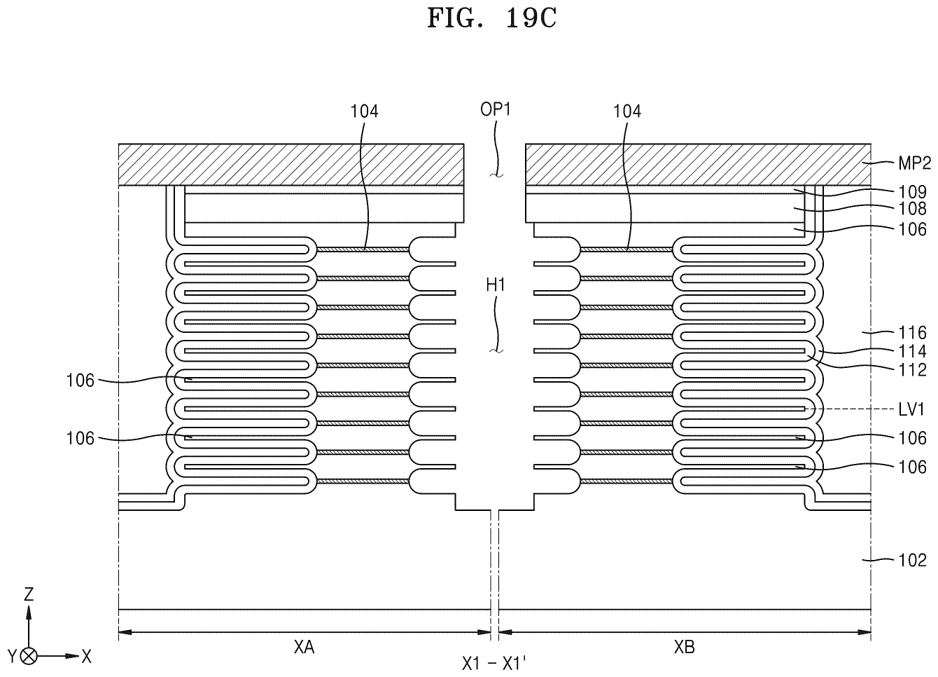

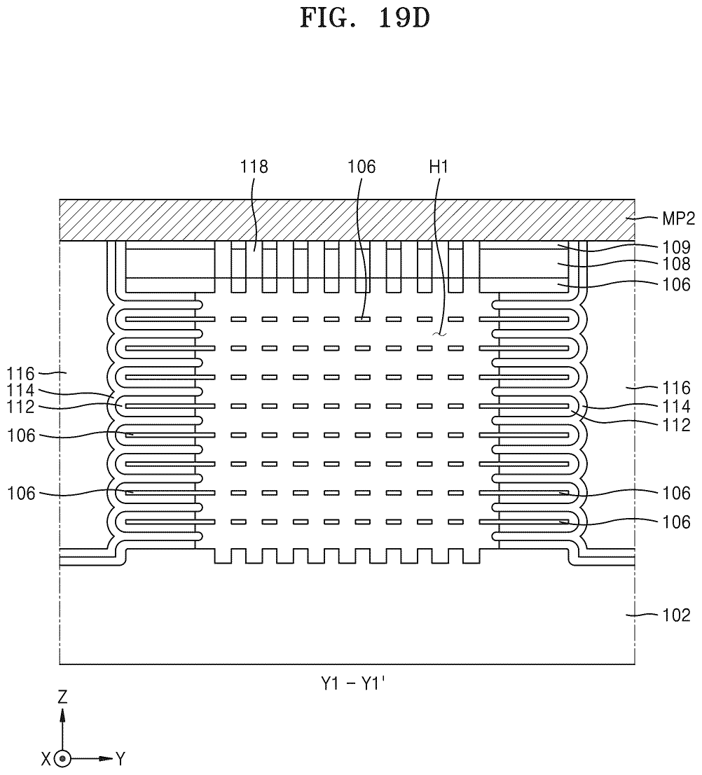

Referring to FIGS. 19A, 19B, 19C, and 19D, portions of the plurality of sacrificial layers 104 may be removed through the plurality of first openings OP1 and the plurality of holes H1 from the resultant structure FIGS. 18A, 18B, and 18C. Also, each of the plurality of active layers 106 may be removed by a partial thickness through spaces where the portions of the plurality of sacrificial layers 104 are removed, and thus, a thickness of the active layer 106 in the vertical direction (Z direction) may be reduced in a partial region of each of the plurality of active layers 106. As shown in FIG. 19B, respective portions of the plurality of insulating plugs 118 exposed through the plurality of first openings OP1 and the plurality of holes H1 may be removed, and thus, a width of each of the plurality of insulating plugs 118 in the first lateral direction (X direction) may be reduced.

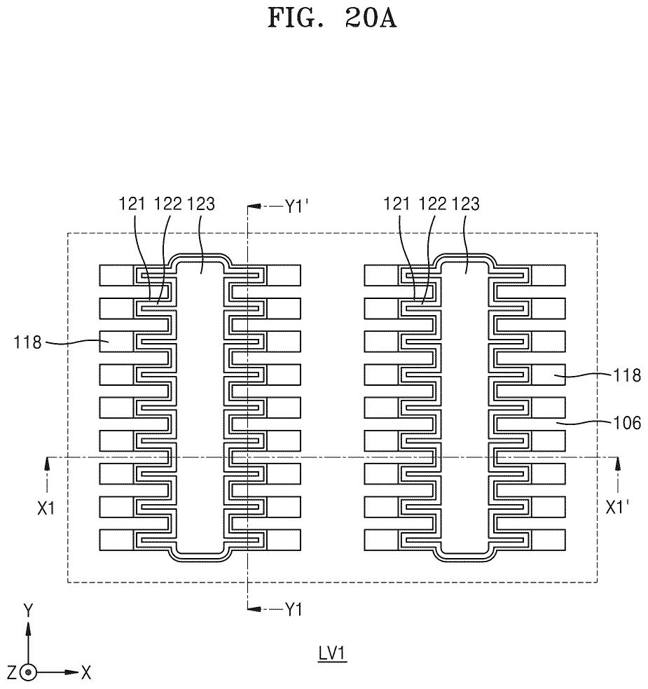

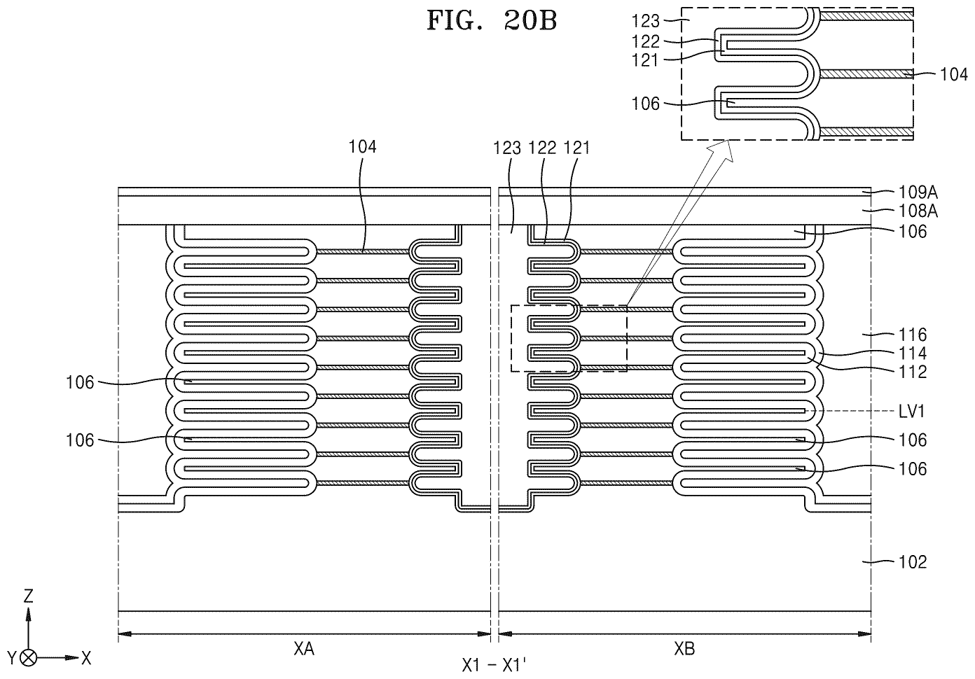

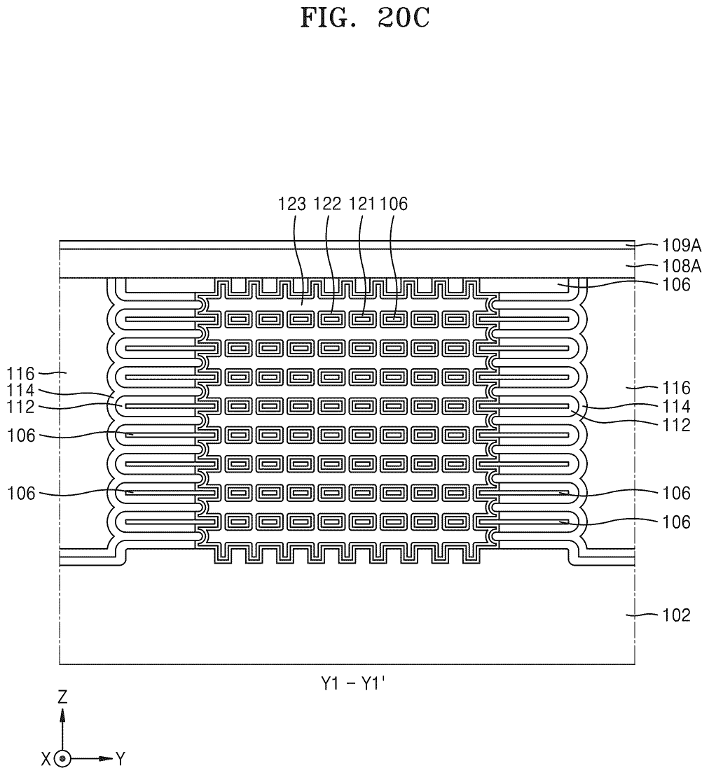

Referring to FIGS. 20A, 20B, and 20C, in the resultant structure of FIGS. 19A, 19B, 19C, and 19D, a third insulating liner 121 and a fourth insulating liner 122 may be formed to conformally cover surfaces exposed through the plurality of holes H1, and a first buried insulating film 123 may be formed to fill the remaining spaces of the plurality of holes H1 defined by the fourth insulating liner 122. In some example embodiments, the third insulating liner 121 may include silicon oxide, the fourth insulating liner 122 may include silicon nitride, and the first buried insulating film 123 may include silicon oxide.

Thereafter, the mask pattern MP2, the silicon nitride film 109, and the silicon oxide film 108 may be removed by using a CMP process. Thus, a planar top surface at which a plurality of active layers 106 located at a farthest vertical level from the substrate 102, from among the plurality of active layers 106, are exposed may be formed. Afterwards, a silicon oxide film (e.g., silicon oxide pattern) 108A and a silicon nitride film (e.g., silicon nitride pattern) 109A may be formed on the resultant structure.

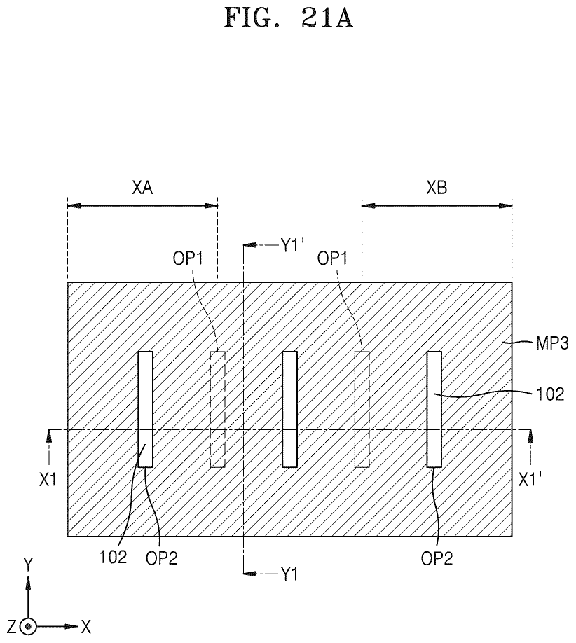

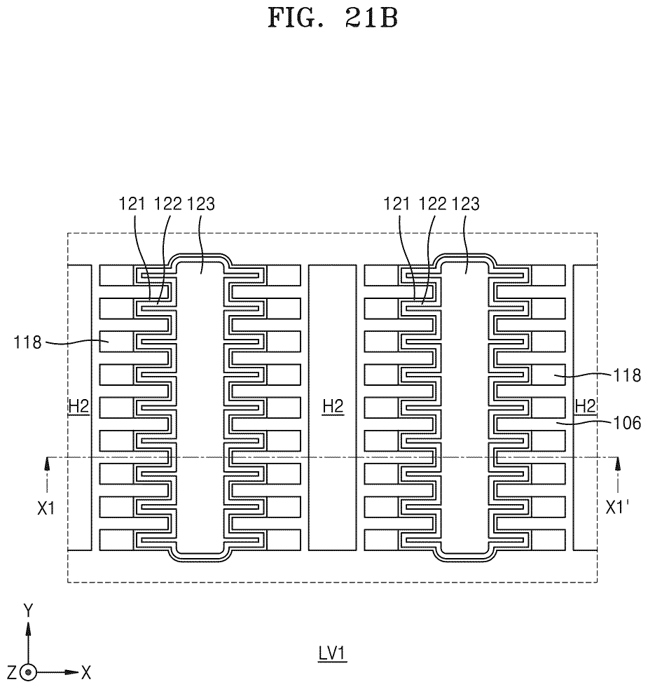

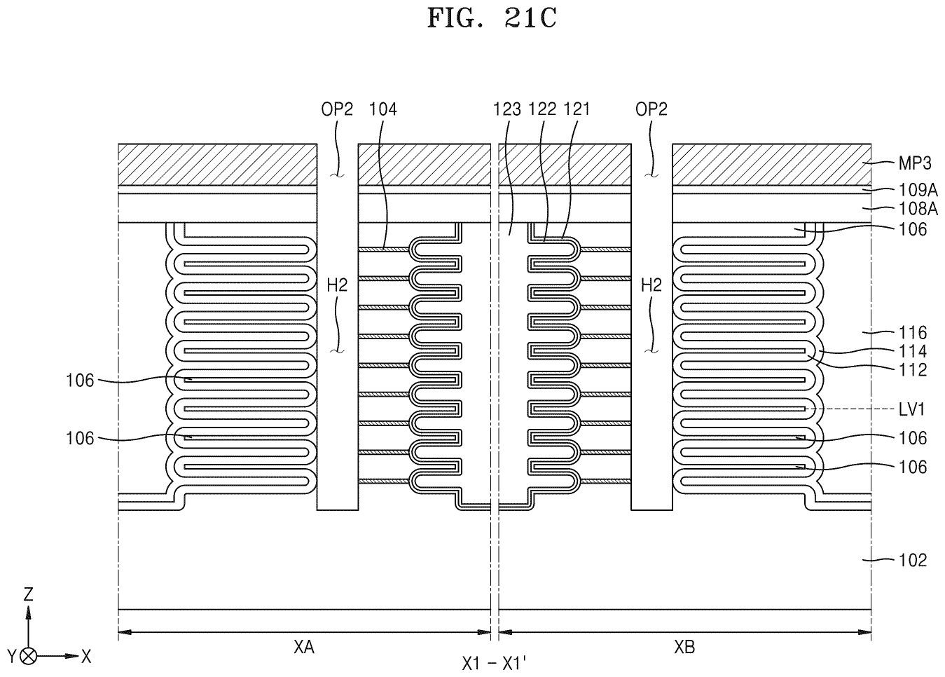

Referring to FIGS. 21A, 21B, and 21C, a mask pattern MP3 may be formed on the silicon nitride film 109A. The mask pattern MP3 may include a plurality of second openings OP2. The plurality of second openings OP2 may be at positions obtained by moving the plurality of first openings OP1 formed in the mask pattern MP2 shown in FIG. 18A by a distance corresponding to ½ a pitch of the plurality of first openings OP1 in the first lateral direction (X direction). For brevity, positions of the plurality of first openings OP1 formed in the mask pattern MP2 shown in FIG. 18A are illustrated with dashed lines in FIG. 21A.

The stack structure including the plurality of sacrificial layers 104 and the plurality of active layers 106 may be etched through the plurality of second openings OP2 by using the mask pattern MP3 as an etch mask, and thus, a plurality of holes H2 exposing the substrate 102 may be formed in the stack structure. The plurality of second openings OP2 may include a pair of second openings OP2 at both ends in the first lateral direction (X direction), and a pair of holes H2 formed through the pair of second openings OP2 may be adjacent to positions where the plurality of word line pads WLP shown in FIG. 4 are to be formed.

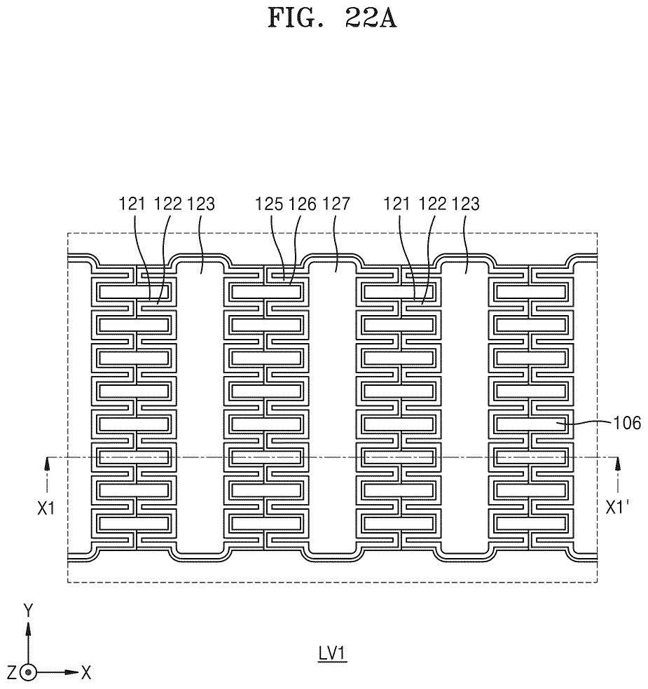

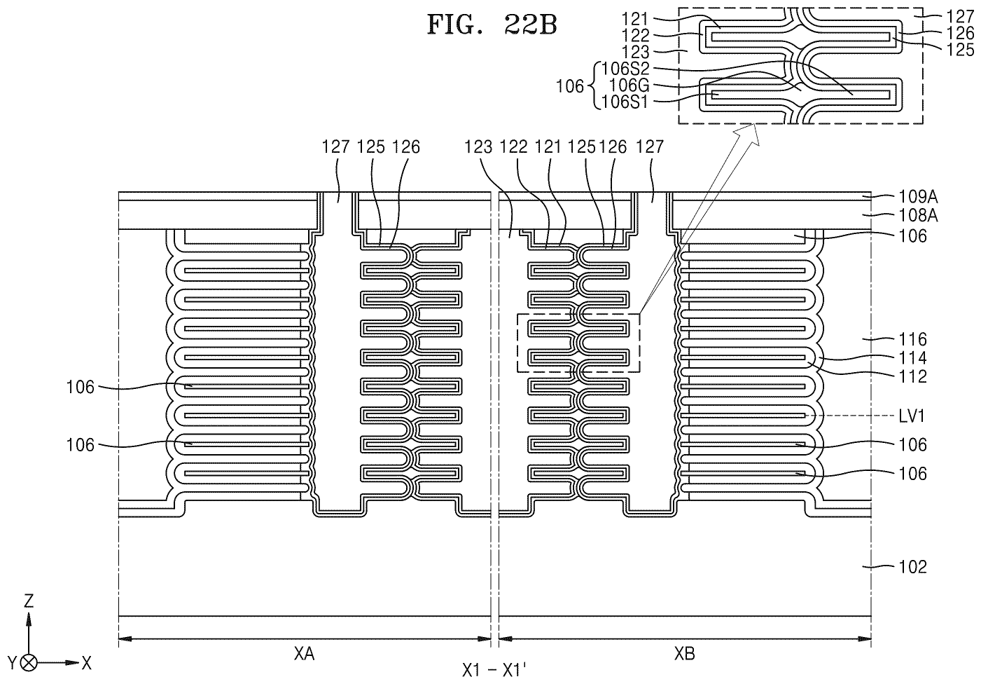

Referring to FIGS. 22A and 22B, the plurality of sacrificial layers 104 exposed through the plurality of holes H2 may be removed from the resultant structure of FIGS. 21A, 21B, and 21C. Also, each of the plurality of active layers 106 may be removed by a partial thickness through spaces where portions of the plurality of sacrificial layers 104 are removed. Thus, a thickness of each of the active layers 106 in the vertical direction (Z direction) may be reduced in a partial region of the corresponding one of the plurality of active layers 106.

Similar to the description provided with reference to FIG. 19B, the plurality of insulating plugs 118 exposed through the plurality of second openings OP2 and the plurality of holes H2 may be removed. A fifth insulating liner 125 and a sixth insulating liner 126 may be formed to conformally cover the surfaces exposed through the plurality of holes H2 in the resultant structure, and a second buried insulating film 127 may be formed to fill the remaining spaces of the plurality of holes H2 defined by the sixth insulating liner 126. In some example embodiments, the fifth insulating liner 125 may include silicon oxide, the sixth insulating liner 126 may include silicon nitride, and the second buried insulating film 127 may include silicon oxide.

Thereafter, the mask pattern MP2, a silicon nitride film 109, and a silicon oxide film 108 may be removed by using a CMP process to expose a top surface of the silicon nitride film 109A.

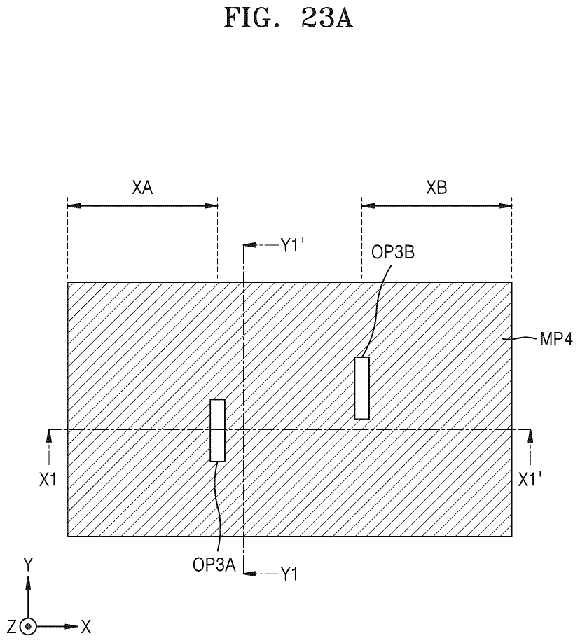

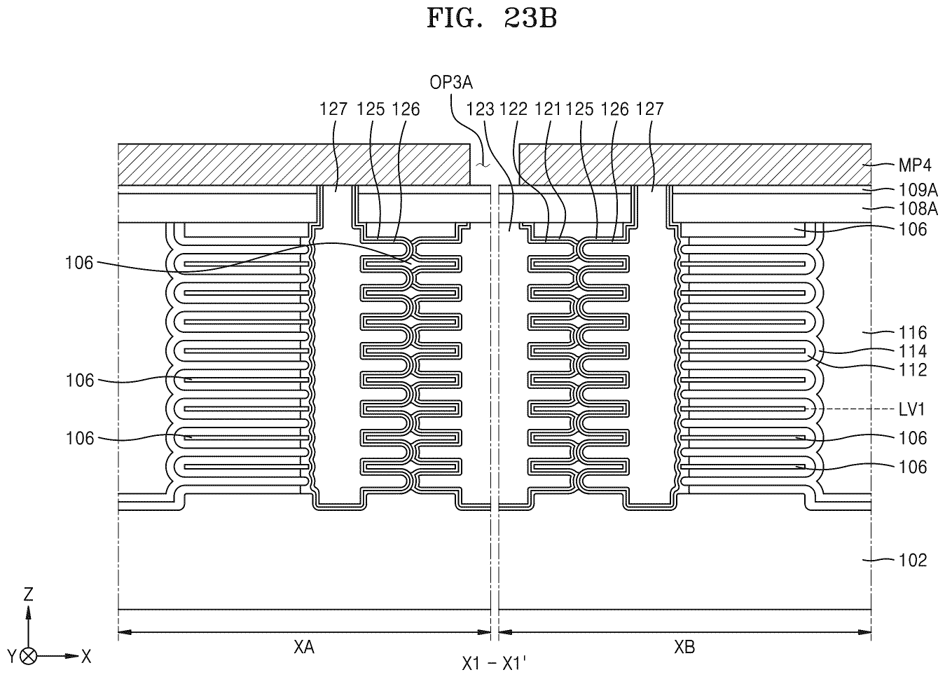

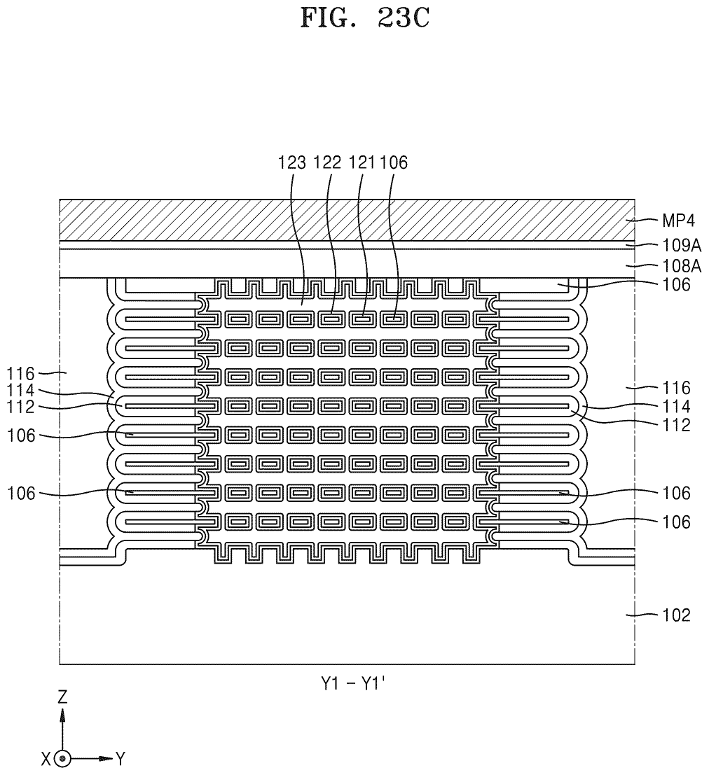

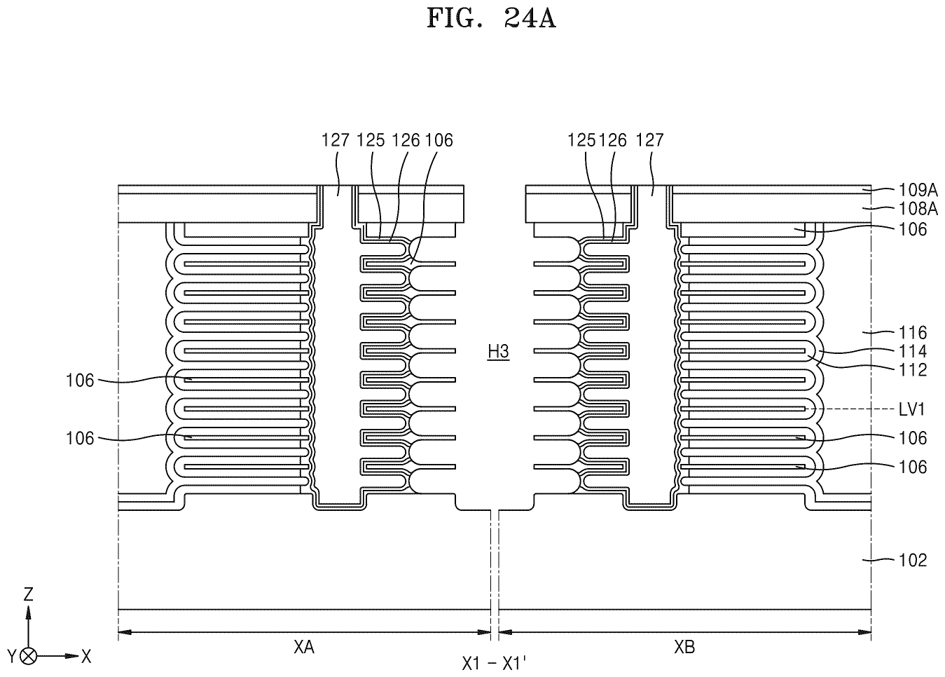

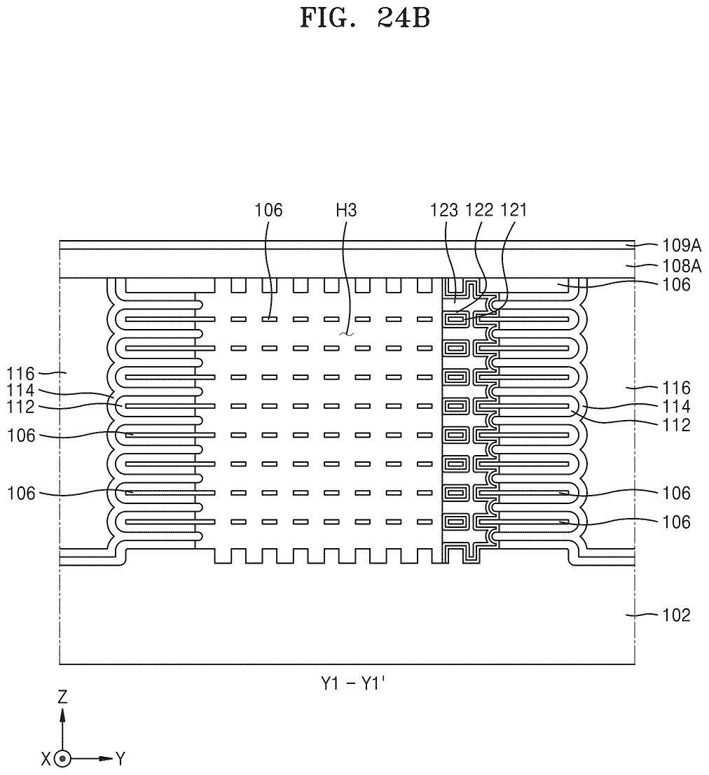

Referring to FIGS. 23A, 23B, and 23C, a mask pattern MP4 may be formed on the resultant structure on which the processes described with reference to FIGS. 22A and 22B have been performed. The mask pattern MP4 may include a plurality of third openings OP3 A and OP3B. As shown in FIG. 23A, the plurality of third openings OP3A and OP3B may be at positions similar to positions of the plurality of first openings OP1 formed in the mask pattern MP2 shown in FIG. 18A in the first lateral direction (X direction). However, from among the plurality of third openings OP3A and OP3B, one third opening OP3A and another third opening OP3B corresponding thereto may be misaligned (e.g., offset) from each other in opposite directions in a second lateral direction (Y direction).

Referring to FIGS. 24A and 24B, the silicon nitride film 109A and the silicon oxide film 108A may be sequentially etched through the plurality of third openings OP3A and OP3B by using the mask pattern MP4 formed in the process described with reference to FIGS. 23A, 23B, and 23C as an etch mask. Subsequently, the first buried insulating film 123, the fourth insulating liner 122, and the third insulating liner 121 may be sequentially removed to form a plurality of holes H3 exposing the plurality of active layers 106 and the substrate 102. Afterwards, the mask pattern MP4 may be removed to expose the top surface of the silicon nitride film 109A.

In the mask pattern MP4, from among the plurality of third openings OP3A and OP3B, one third opening OP3A and another third opening OP3B corresponding thereto may be misaligned (e.g., offset) from each other in opposite directions in the second lateral direction (Y direction). Thus, as shown in FIG. 24B, a portion of each of the third insulating liner 121, the fourth insulating liner 122, and the first buried insulating film 123 may remain on the substrate 102 in a partial region adjacent to one end portion in the second lateral direction (Y direction).

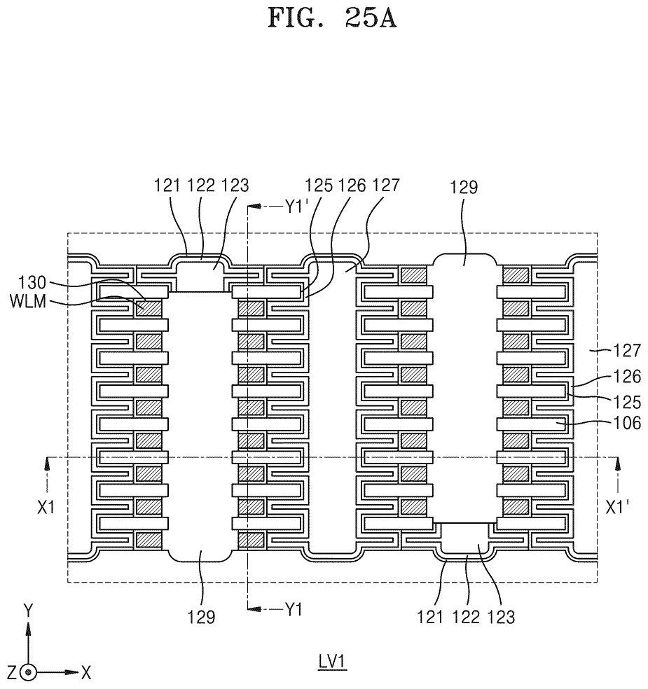

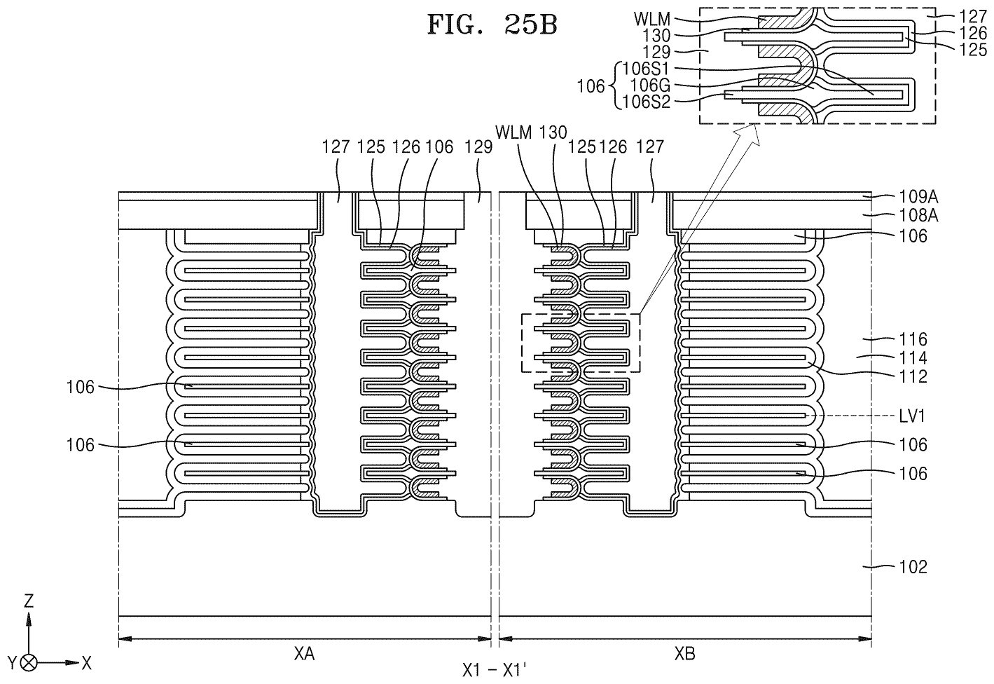

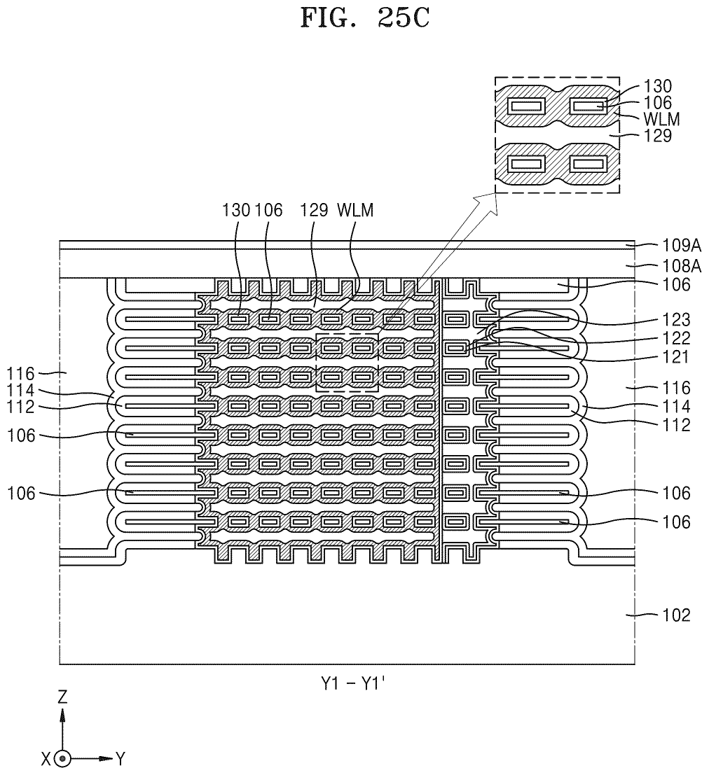

Referring to FIGS. 25A, 25B, and 25C, in the resultant structure on which the processes described with reference to FIGS. 24A and 24B have been performed, a gate dielectric film 130 may formed to conformally cover surfaces exposed at the plurality of holes H3, a conductive layer may be formed to cover a surface of the gate dielectric film 130, and a protective pattern may be formed to cover portions of the conductive layer, which are desired to be left. Thereafter, exposed portions of the conductive layer may be selectively removed by using the protective pattern as an etch mask, and thus, a plurality of conductive patterns WLM for forming a plurality of word lines may be formed. Thereafter, the remaining spaces of the plurality of holes H3 may be filled by an insulating structure 129. The insulating structure 129 may include a silicon oxide film, a silicon nitride film, or a combination thereof. In some example embodiments, the insulating structure 129 may include a silicon oxide liner, a silicon nitride liner, and a buried silicon oxide film, which are sequentially stacked on surfaces of the gate dielectric film 130 and the plurality of conductive patterns WLM.

Referring to FIGS. 26A, 26B, 26C, and 26D, a mask pattern MP5 exposing the buried insulating film 116 may be formed on the resultant structure of FIGS. 25A, 25B, and 25C, and a portion of the buried insulating film 116 may be etched using the mask pattern MP5 as an etch mask. Thus, a thickness of a portion of the buried insulating film 116 that covers an outer sidewall of the second insulating liner 114 may be reduced.

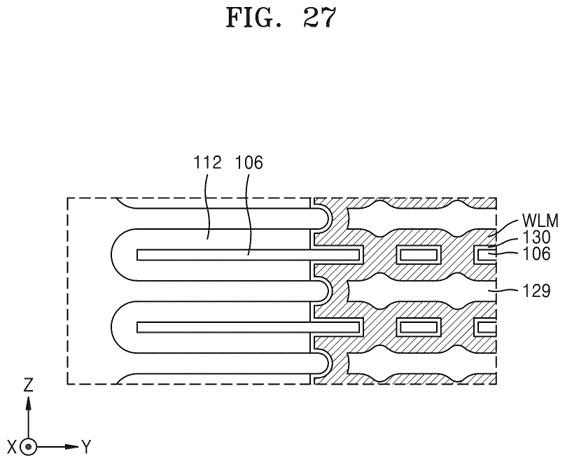

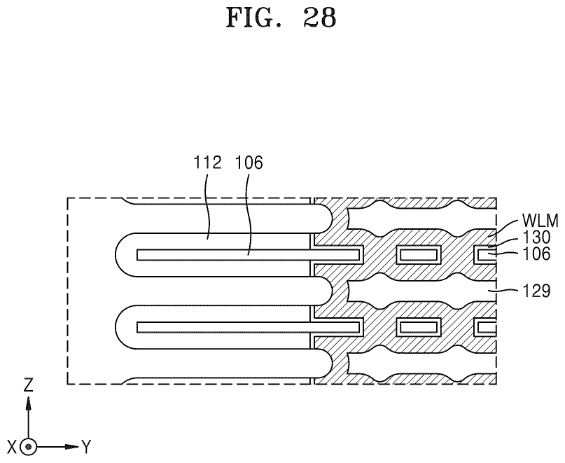

FIGS. 27 and 28 are enlarged cross-sectional views illustrating a subsequent process on a portion corresponding to portion “EX1” of FIG. 26C. As shown in FIG. 27, the buried insulating film 116 exposed in the resultant structure of FIGS. 26A, 26B, 26C, and 26D may be removed to expose the gate dielectric film 130. Next, as shown in FIG. 28, exposed portions of the gate dielectric film 130 may be removed to expose partial regions of the conductive pattern WLM.

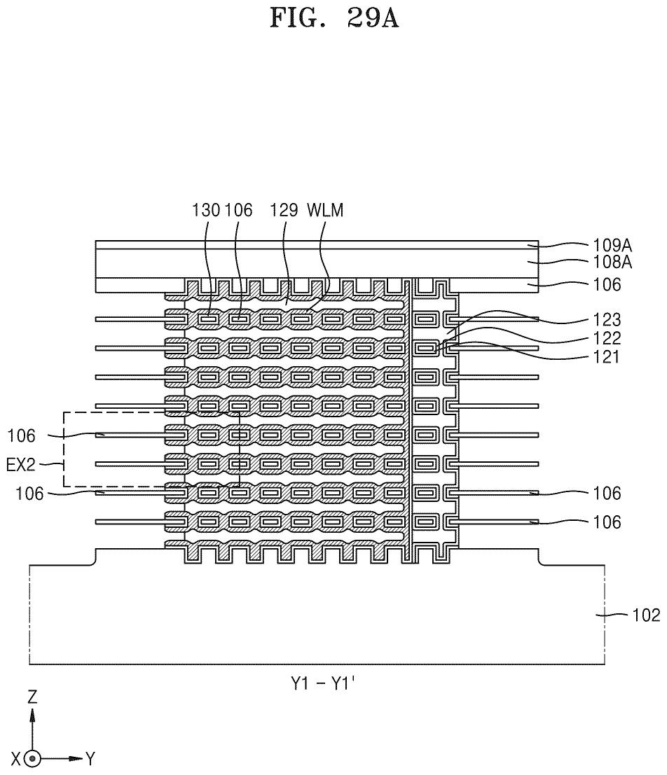

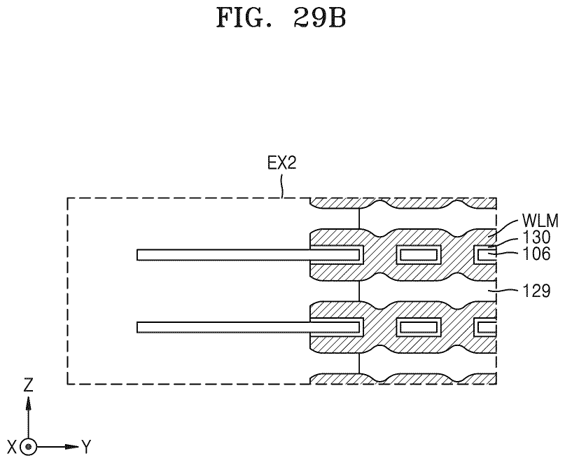

Referring to FIGS. 29A and 29B, the exposed partial regions of the conductive pattern WLM may be etched, and thus, the conductive pattern WLM may be separated into a plurality of conductive patterns WLM, which are isolated from each other at a plurality of vertical levels. Thereafter, the first insulating liner 112 covering the plurality of active layers 106 may be removed, and thus, the plurality of active layers 106 may be exposed around the plurality of conductive patterns WLM.

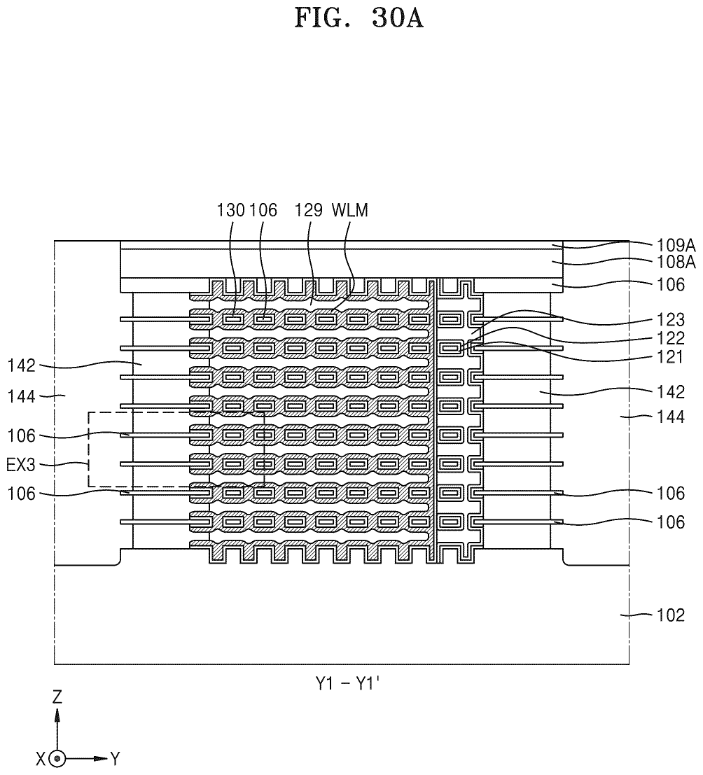

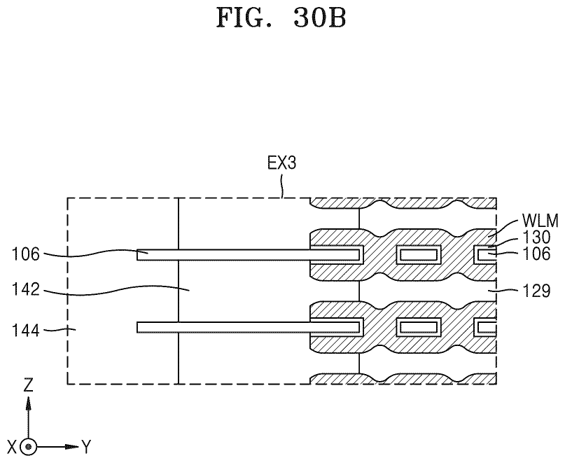

Referring to FIGS. 30A and 30B, an insulating film 142 filling respective spaces between the plurality of active layers 106 and covering the plurality of conductive patterns WLM may be formed around the plurality of conductive patterns WLM. Thereafter, a portion of the insulating film 142 may be removed again, and thus, the plurality of active layers 106 may be exposed at an outer sidewall of the insulating film 142. Thereafter, an outer insulating film 144 may be formed to fill spaces in which the outer sidewall of the insulating film 142 and the plurality of active layers 106 are exposed, and the resultant structure may be planarized by using a CMP process to expose a top surface of the silicon nitride film 109A. In some example embodiments, the insulating film 142 may include a silicon nitride film, and the outer insulating film 144 may include a silicon oxide film.

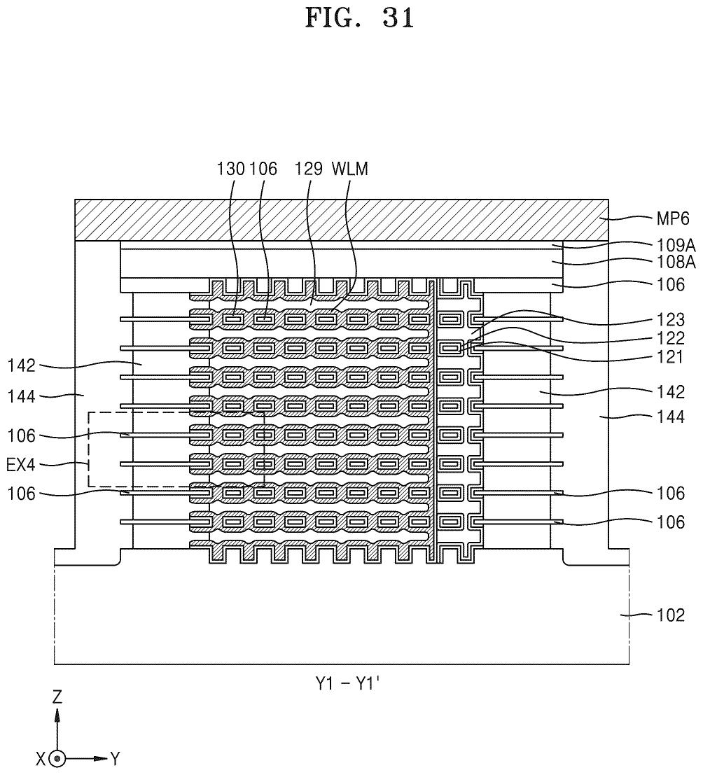

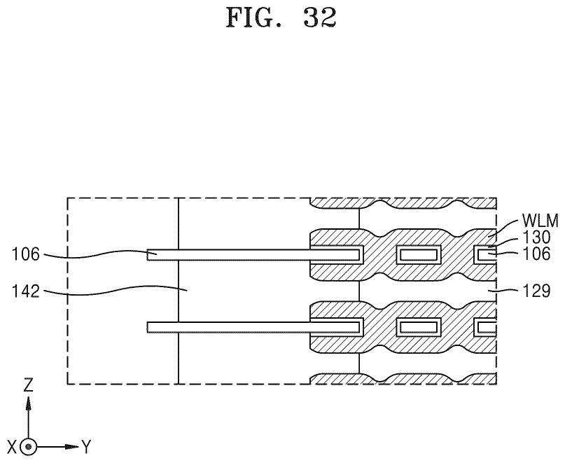

Referring to FIG. 31, a mask pattern MP6 may be formed on the resultant structure on which the processes described with reference to FIGS. 30A and 30B have been performed. A top surface of the outer insulating film 144 may be exposed around the mask pattern MP6. A portion of the outer insulating film 144 may be etched by using the mask pattern MP6 as an etch mask, and thus, a thickness of a portion of the outer insulating film 144, which covers a sidewall of the insulating film 142, may be reduced.

FIGS. 32 to 35 are enlarged cross-sectional views illustrating a subsequent process on a portion corresponding to portion “EX4” of FIG. 31.

Referring to FIG. 32, the mask pattern MP6 and the outer insulating film 144 may be removed from the resultant structure on which the processes described with reference to FIG. 31 to expose the insulating film 142 and the plurality of active layers 106 have been performed.

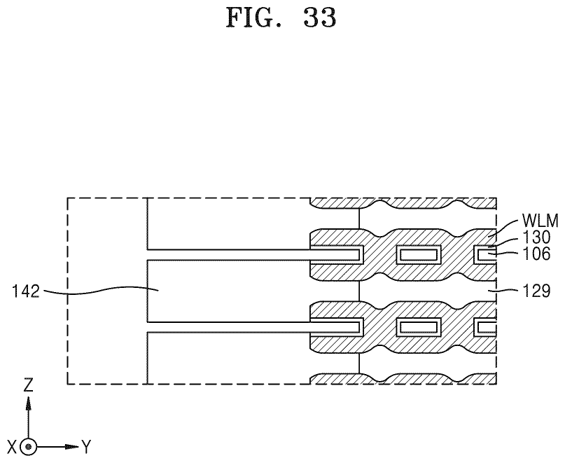

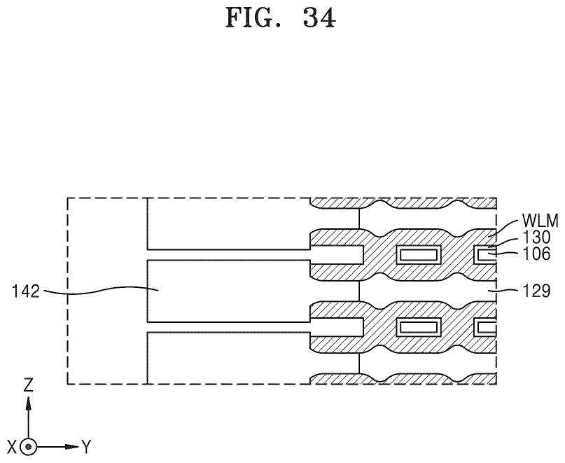

Referring to FIG. 33, the plurality of active layers 106 exposed in the resultant structure on which the processes described with reference to FIG. 32 may be removed, and thus, a plurality of gate dielectric films 130 may be exposed through spaces from the plurality of active layers 106 are removed.

Referring to FIG. 34, the plurality of gate dielectric films 130 exposed in the resultant structure on which the processes described with reference to FIG. 33 may be removed to expose the plurality of conductive patterns WLM.

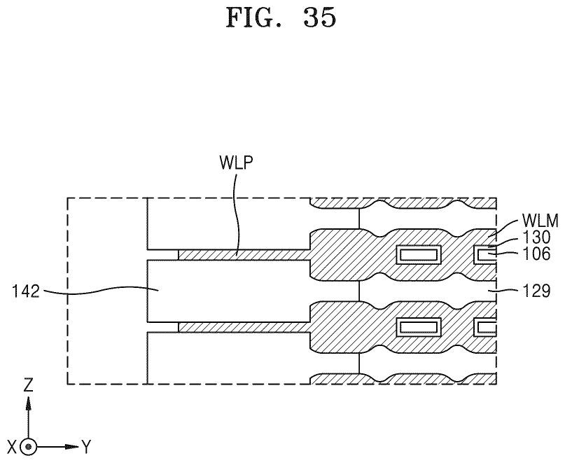

Referring to FIG. 35, spaces formed by removing the plurality of active layers 106 and the plurality of gate dielectric films 130 may be filled by a conductive material to form a plurality of word line pads WLP.

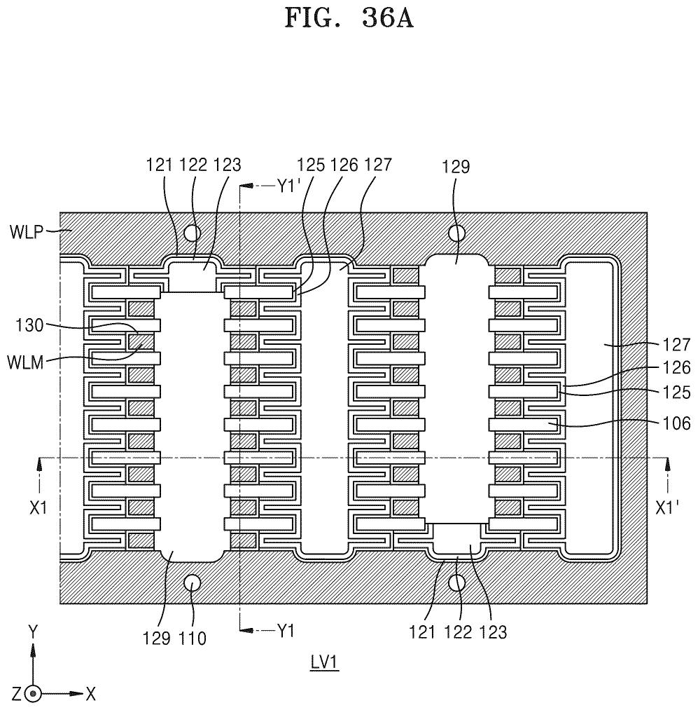

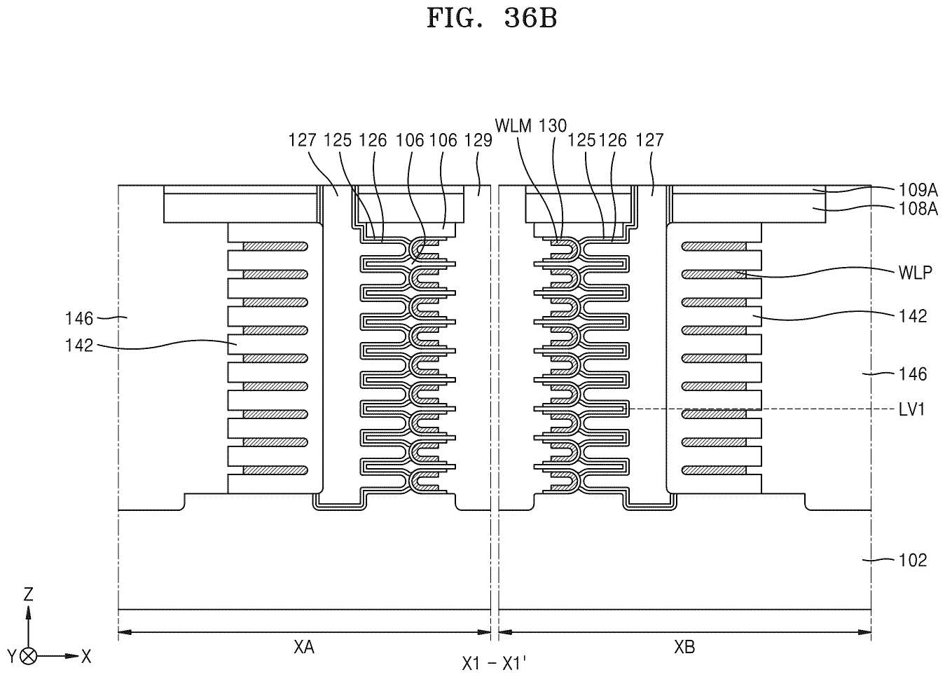

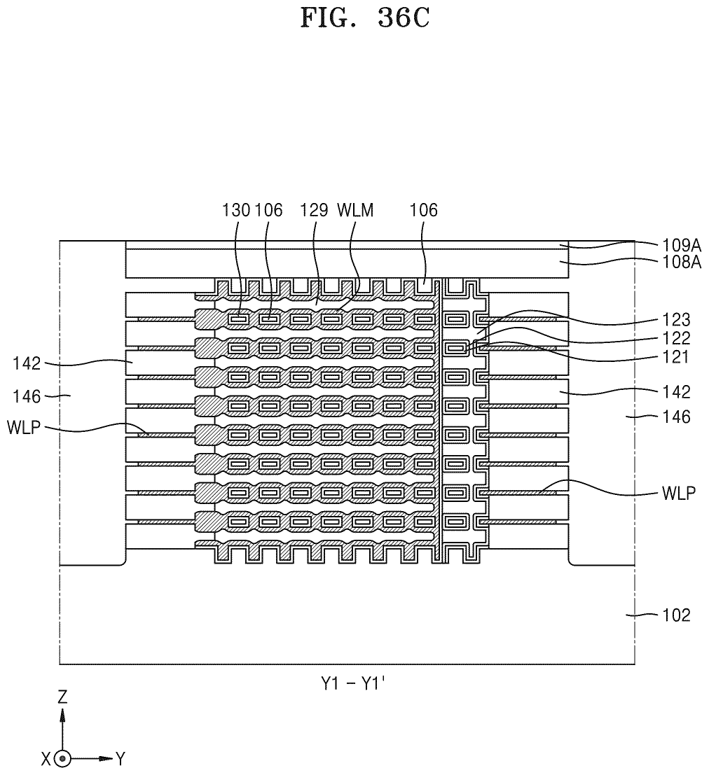

Referring to FIGS. 36A, 36B, and 36C, in the resultant structure on which the processes described with reference to FIG. 35 have been performed, an insulating film 146 covering the plurality of word line pads WLP may be formed, and a top surface of the insulating film 146 may be then planarized. The insulating film 146 may include a silicon oxide film, a silicon nitride film, or a combination thereof. For example, the insulating film 146 may include a silicon oxide film.

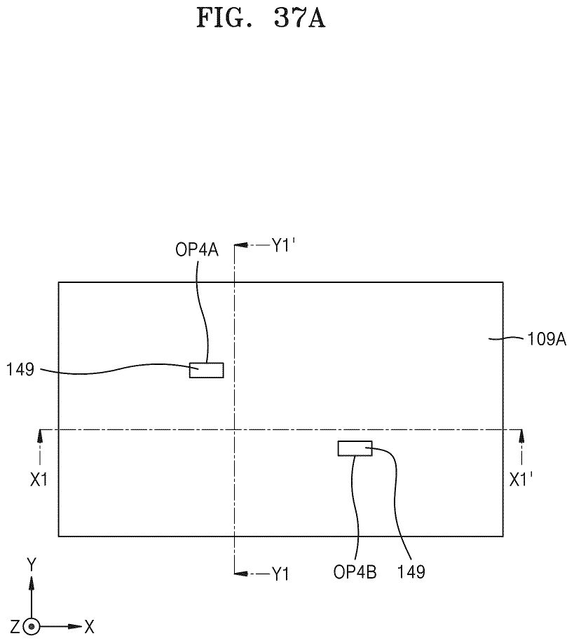

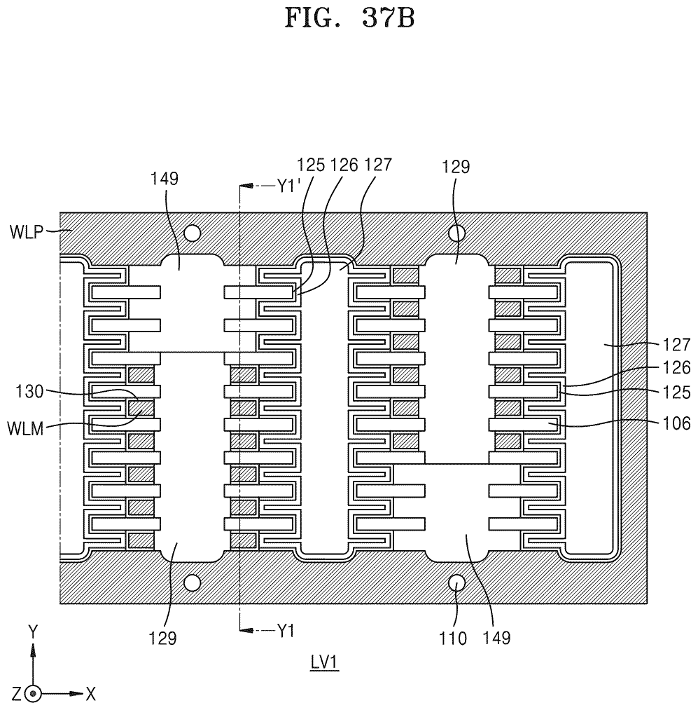

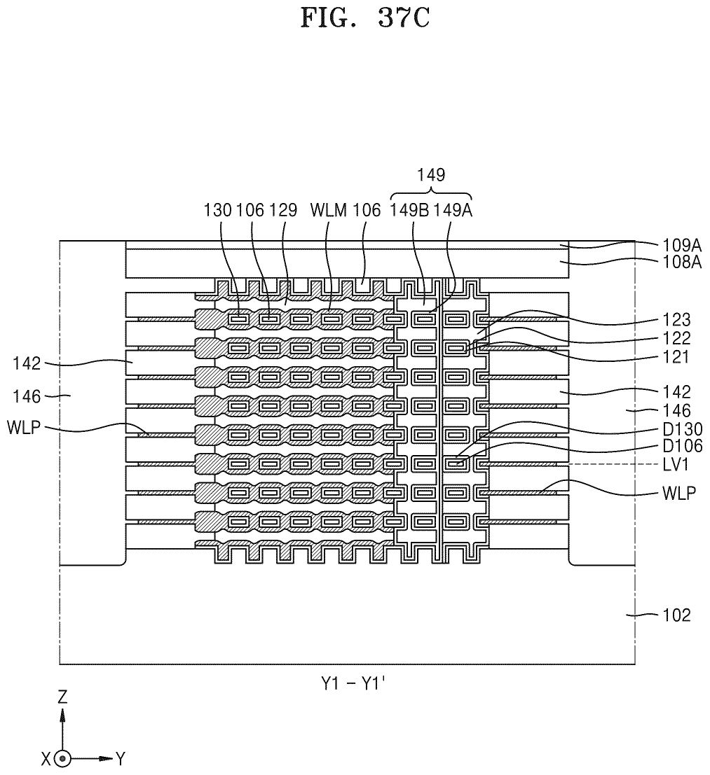

Referring to FIGS. 37A, 37B, and 37C, in the resultant structure of FIGS. 36A, 36B, and 36C, a plurality of fourth openings OP4A and OP4B may be formed in the silicon oxide film 108A and the silicon nitride film 109A by using a mask pattern. The plurality of fourth openings OP4A and OP4B may be at positions similar to positions of the plurality of first openings OP1 formed in the mask pattern MP2 shown in FIG. 18A in the first lateral direction (X direction). However, from among the plurality of fourth openings OP4A and OP4B, one fourth opening OP4A and another fourth opening OP4A may be misaligned (e.g., offset) from each other in opposite directions in the second lateral direction (Y direction).

Thereafter, the third insulating liner 121, the fourth insulating liner 122, and the first buried insulating film 123, which are exposed through the plurality of fourth openings OP4A and OP4B, may be removed, and a portion of the insulating structure 129 may be removed. Portions of the plurality of conductive patterns WLM and portions of the plurality of gate dielectric films 130, which are exposed as the result of the removal process, may be removed to form a plurality of spaces. Afterwards, the plurality of spaces may be filled by a plurality of insulating blocks 149. In some example embodiments, each of the plurality of insulating blocks 149 may include a silicon nitride liner 149A surrounding the active layer 106 and the gate dielectric film 130 and a silicon oxide film 149B filling spaces defined by the silicon nitride liner 149A. As shown in FIG. 37C, portions of the active layer 106, which are surrounded by the insulating block 149, may constitute a dummy active region D106, and portions of the gate dielectric film 130, which are surrounded by the insulating block 149, may constitute a dummy gate dielectric film D130.

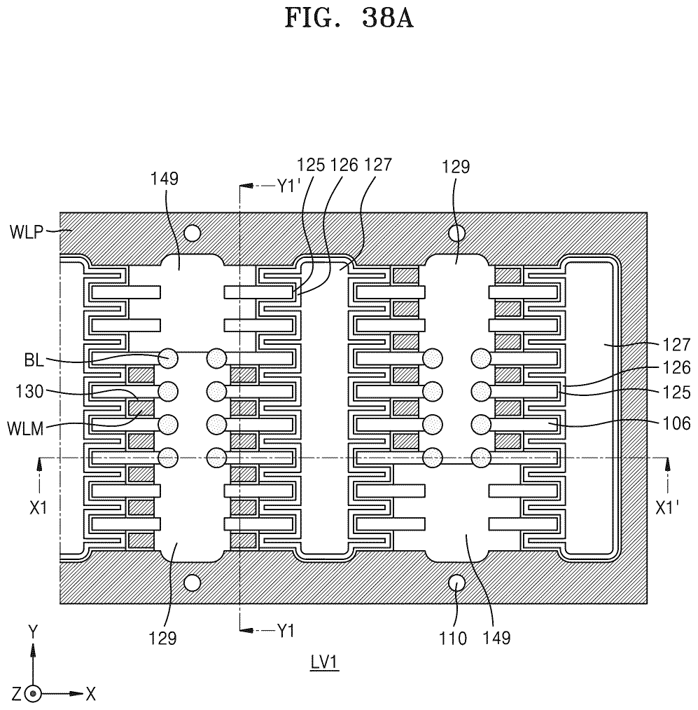

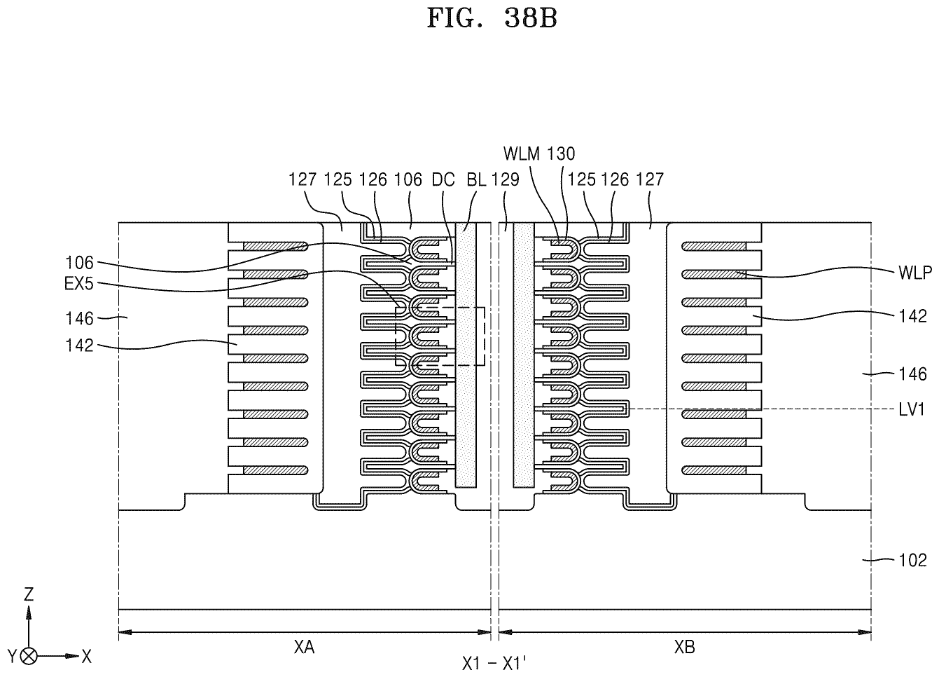

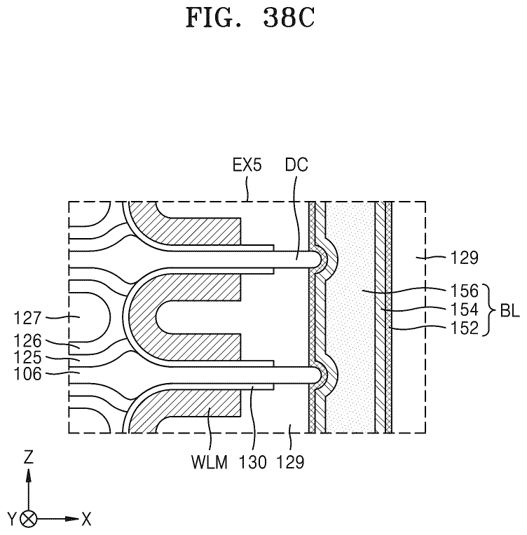

Referring to FIGS. 38A, 38B, and 38C, in the resultant structure on which the processes described with reference to FIGS. 37A, 37B, and 37C have been performed, a plurality of bit lines BL passing through a portion of the insulating structure 129 in the vertical direction (Z direction) may be formed. The plurality of bit lines BL may be formed to contact the plurality of active layers 106, which are arranged in a line in the vertical direction (Z direction). To form the plurality of bit lines BL, a plurality of vertical holes may be formed to pass through a portion of the insulating structure 129 in the vertical direction (Z direction). The plurality of active layers 106, which are arranged in a line in the vertical direction (Z direction), may be exposed through the plurality of vertical holes. Each of the plurality of active layers 106 exposed through the plurality of vertical holes may be doped with a dopant to form a direct contact DC. Thereafter, a metal silicide film 152, a conductive liner 154, and a conductive plug 156 may be sequentially formed inside each of the plurality of vertical holes.

Thereafter, a silicon nitride film 109A and a silicon oxide film 108A may be removed by using a CMP process. Subsequently, a planar top surface at which a plurality of active layers 106 located at a farthest vertical level from the substrate 102, from among the plurality of active layers 106, are exposed may be formed.

Referring to FIGS. 39A, 39B, 39C, and 39D, a mask pattern 160 may be formed to cover the resultant structure on which the processes described with reference to FIGS. 38A, 38B, and 38C have been performed. The mask pattern 160 may include a plurality of fifth openings OP5. In a view from above, positions of the plurality of fifth openings OP5 may substantially be the same as positions of the plurality of second openings OP2 shown in FIG. 21A. The mask pattern 160 may include a silicon nitride film.

The fifth insulating liner 125, the sixth insulating liner 126, and the second buried insulating film 127 may be removed through the plurality of fifth openings OP5, and thus, a plurality of holes H4 exposing the plurality of active layers 106, the plurality of gate dielectric films 130, and the substrate 102 may be formed. Thereafter, portions of the plurality of gate dielectric films 130 may be exposed through the plurality of holes H4, respectively. Next, exposed portions of the plurality of gate dielectric films 130 may be exposed to expose the plurality of conductive patterns WLM, and the exposed conductive patterns WLM may be etched back and divided into a plurality of word lines WL, respectively. Thus, as shown in an enlarged view of FIG. 39D, the insulating structure 129 may be exposed around the word line WL surrounding one active layer 106 inside the plurality of holes H4.

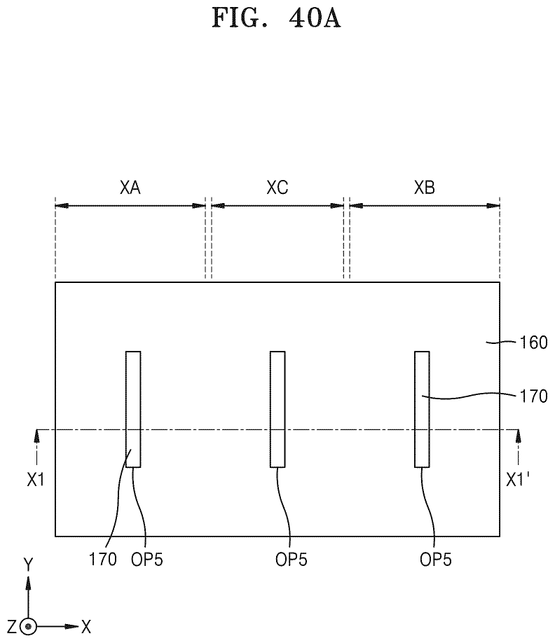

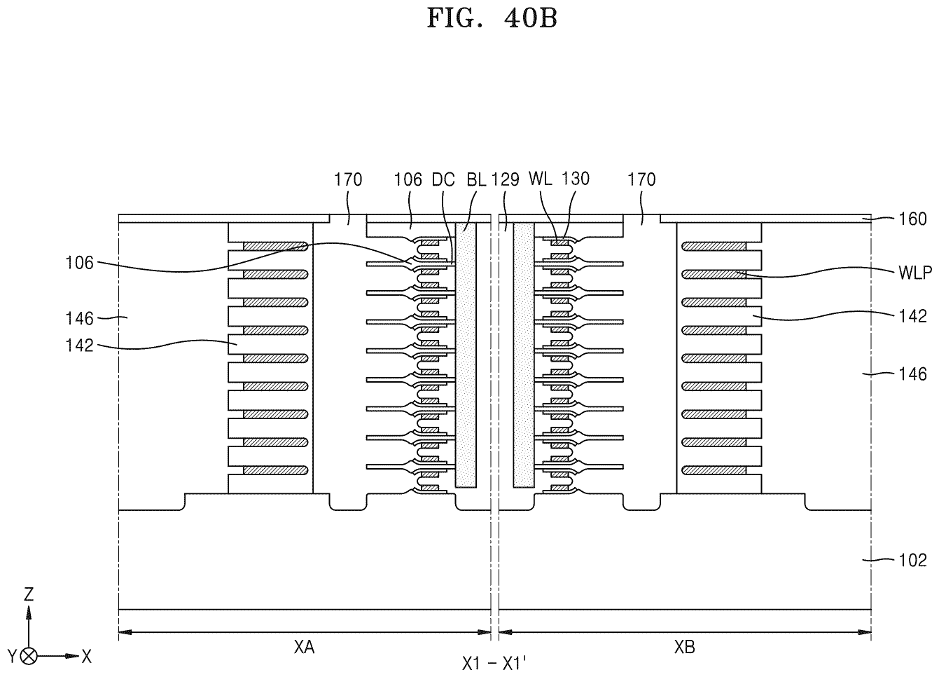

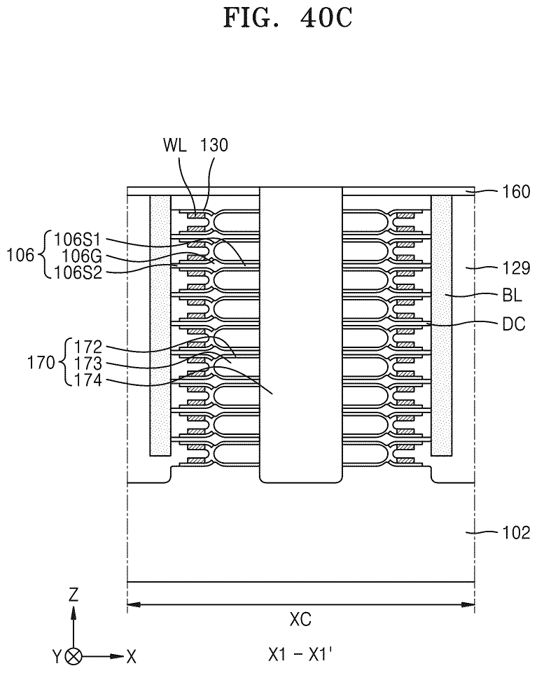

Referring to FIGS. 40A, 40B, and 40C, an insulating structure 170 filling the plurality of holes H4 may be formed on the resultant structure on which the processes described with reference to FIGS. 39A, 39B, 39C, and 39D have been performed. To form the insulating structure 170, initially, respective spaces between the plurality of active layers 106 arranged in a line in the vertical direction (Z direction) may be filled by a seventh insulating liner 172 and a third buried insulating film 173, and the remaining spaces of the plurality of holes H4 may be then filled by an insulating film 174. The insulating film 174 may include a silicon oxide film, a silicon nitride film, or a combination thereof. The seventh insulating liner 172, the third buried insulating film 173, and the insulating film 174 may constitute an insulating structure 170.

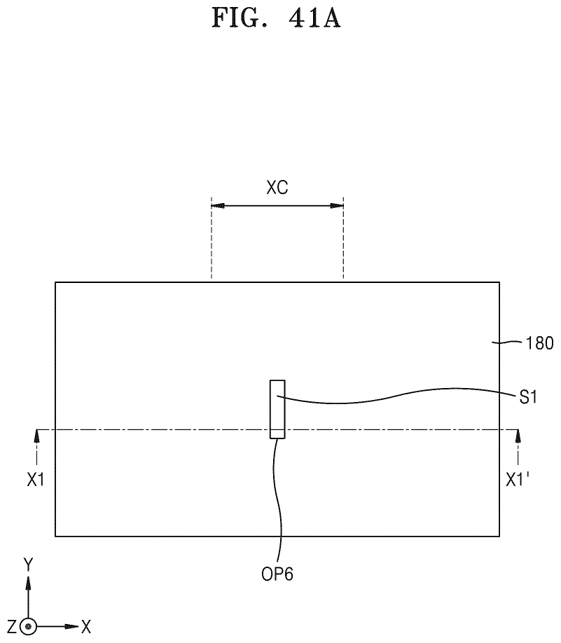

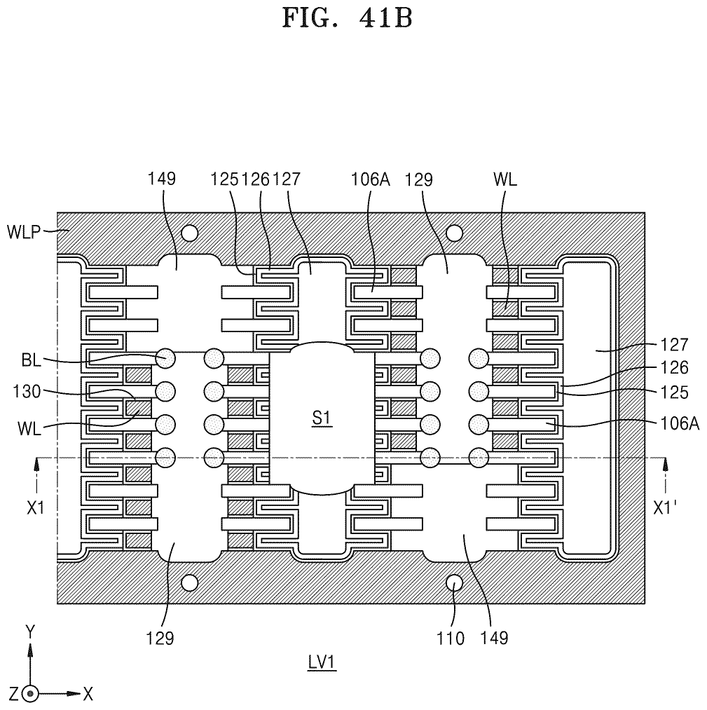

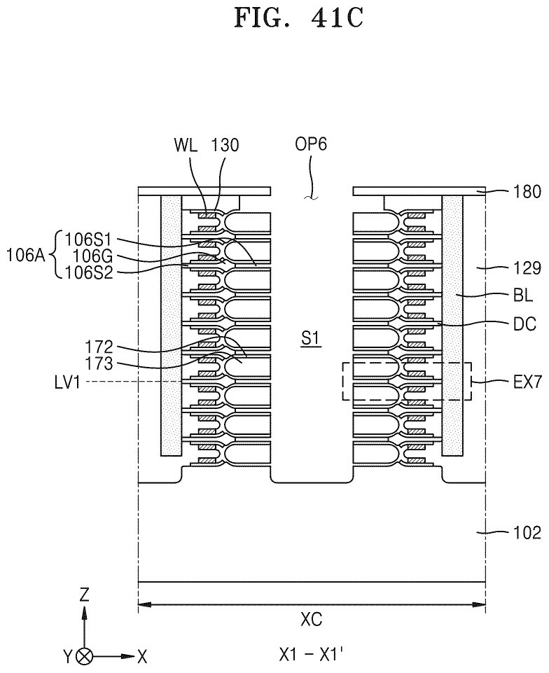

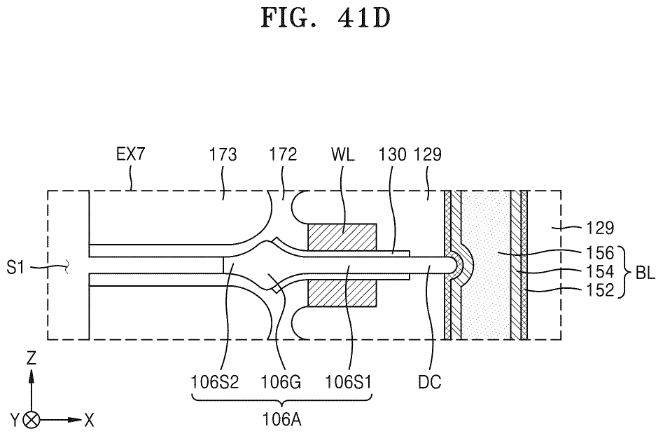

Referring to FIGS. 41A, 41B, and 41C, the mask pattern 160 may be removed to expose a plurality of active layers 106 at a farthest vertical level from the substrate 102, from among the plurality of active layers 106, in the resultant structure on which the processes described with reference to FIGS. 40A, 40B, and 40C have been performed, and the resultant structure may be planarized. A mask pattern 180 may be formed on the resultant structure. The mask pattern 180 may include a sixth opening OP6. In a view from above, a position of the fifth opening OP5 may correspond to a central position of the plate electrode (refer to 190 in FIG. 3). The mask pattern 180 may include a silicon nitride film.

The insulating film 174, which is a portion of the insulating structure 170, may be removed through the sixth opening OP6 of the mask pattern 180 to form an inner space S1. A portion of each of the plurality of active layers 106 exposed through the inner space S1 may be removed to form a plurality of active regions 106A.

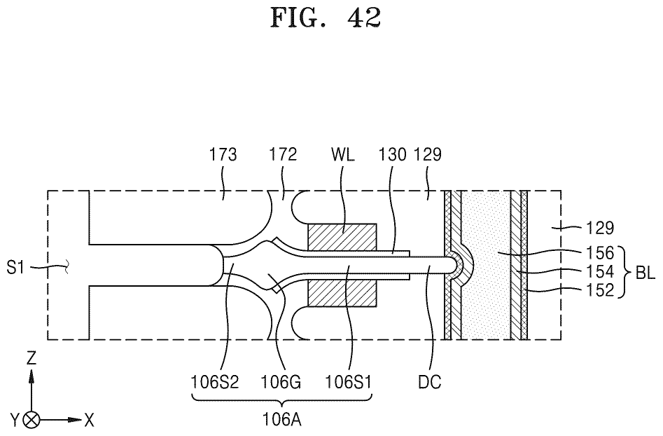

FIGS. 42 to 46 are enlarged cross-sectional views illustrating a subsequent process on a portion corresponding to portion “EX7” of FIG. 41C.

Referring to FIG. 42, a portion of the insulating liner 172 may be removed through an inner space S1 in the resultant structure on which the processes described with reference to FIGS. 41A, 41B, and 41C have been performed. Thus, a vertical distance between two adjacent ones of a plurality of third buried insulating films 173 in the vertical direction (Z direction) may increase in a portion adjacent to the second local portion 106S2 of each of the plurality of active regions 106A.

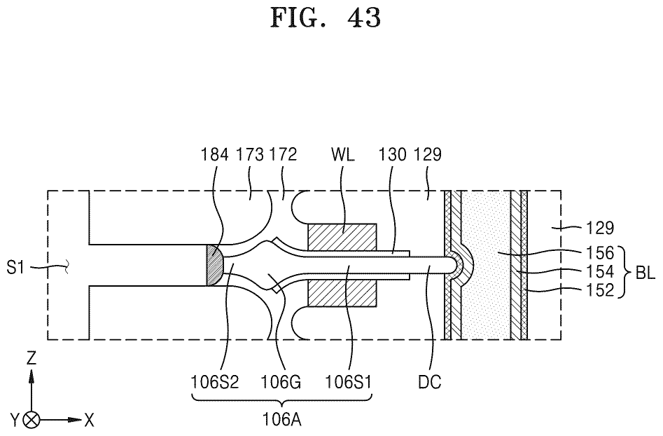

Referring to FIG. 43, a metal silicide film 184 may be formed to contact the second local portion 106S2 of the active region 106A exposed in the inner space S1.

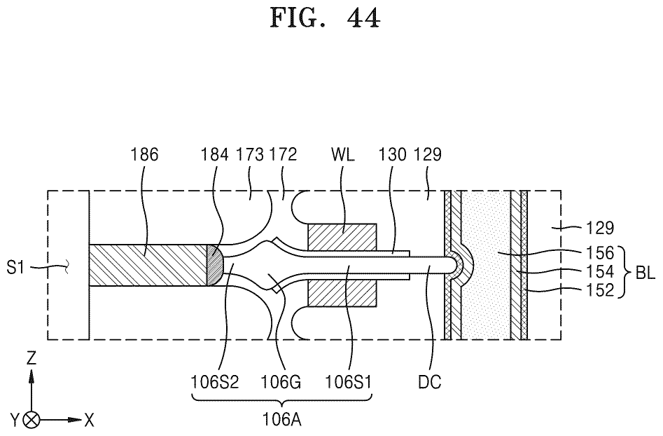

Referring to FIG. 44, a conductive material may be deposited through the inner space S1 in a space between two adjacent ones of the plurality of third buried insulating films 173 in the vertical direction (Z direction), and thus, a plurality of first electrodes 186 may be formed.

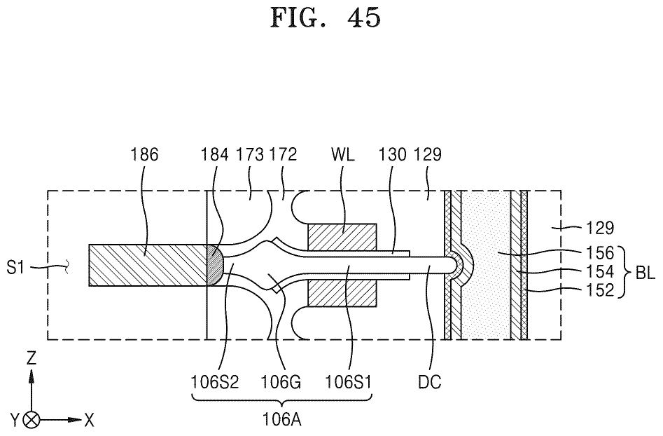

Referring to FIG. 45, respective portions of the plurality of third buried insulating films 173 may be removed, and thus, the plurality of first electrodes 186 may protrude to the outside of the plurality of third buried insulating films 173.

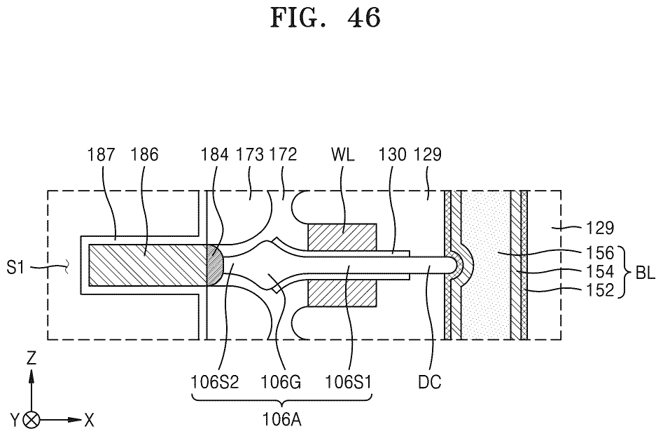

Referring to FIG. 46, a dielectric film 187 conformally covering exposed surfaces including respective surfaces of the plurality of first electrodes 186 may be formed in the inner space S1.

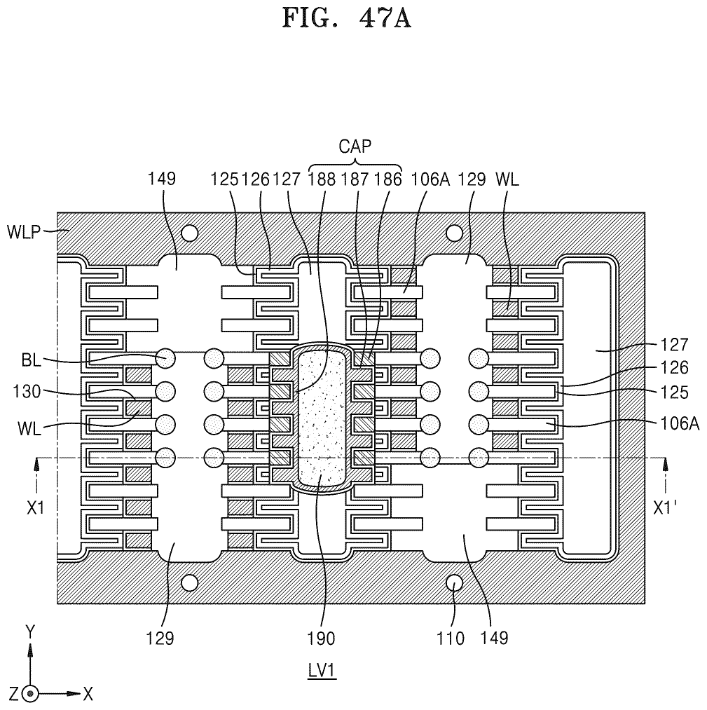

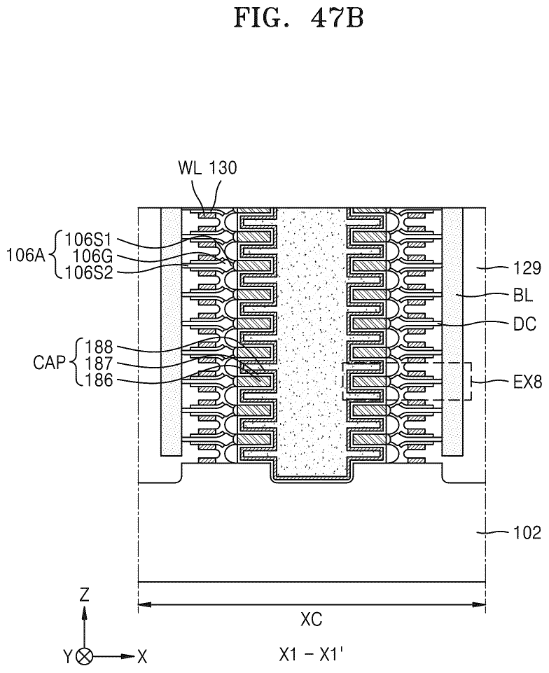

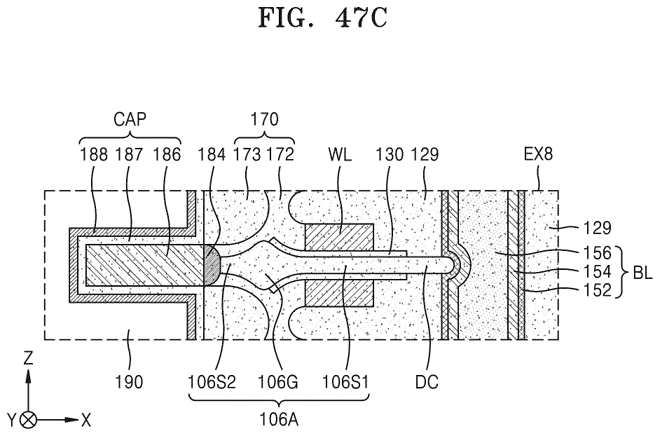

Referring to FIGS. 47A, 47B, and 47C, a second electrode 188 covering the dielectric film 187 may be formed in the inner space S1, and a plate electrode 190 filling the inner space S1 defined by the second electrode 188 may be formed. In some example embodiments, the plate electrode 190 may include a tungsten (W) film. In other example embodiments, the plate electrode 190 may include a combination of a SiGe film and a W film.

Thereafter, as shown in FIG. 3, a partial region of each of the plurality of word line pads WLP stacked on a substrate 102 in the vertical direction (Z direction) may be etched, and thus, the word line pad WLP located at each of a plurality of vertical levels may be separated into a plurality of word line pads WLP.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor memory device comprising:
a plurality of active regions repeatedly arranged in a first lateral direction and a second lateral direction at a first vertical level, the first vertical level being apart from a substrate in a vertical direction, a thickness in the vertical direction of each active region varying in the first lateral direction, the first lateral direction and the second lateral direction being perpendicular to each other;
a first word line surrounding a plurality of first active regions belonging to a first group, the first word line extending lengthwise in the second lateral direction at the first vertical level, the plurality of first active regions being selected from the plurality of active regions and arranged in a line in the second lateral direction;
a second word line surrounding a plurality of second active regions belonging to a second group, the second word line extending lengthwise in the second lateral direction at the first vertical level, the plurality of second active regions being selected from the plurality of active regions and arranged in a line in the second lateral direction, the second word line being apart from the first word line in the first lateral direction; and
a pair of word line pads being at the first vertical level on the substrate, the pair of word line pads being connected to the first word line and the second word line, respectively.

2. The semiconductor memory device of claim 1, wherein, when viewed from above a horizontal cross-section of the semiconductor memory device at the first vertical level, the first word line and the second word line are offset from each other in the second lateral direction.

3. The semiconductor memory device of claim 1, wherein the pair of word line pads comprise a first word line pad and a second word line pad, the first word line pad and the second word line pad being apart from each other with the first word line and the second word line therebetween in the second lateral direction,
the first word line pad is connected to only the first word line, from among the first word line and the second word line, the second word line pad is connected to only the second word line, from among the first word line and the second word line, and
each of the first word line pad and the second word line pad extends lengthwise in the first lateral direction to face both the first word line and the second word line in the second lateral direction.

4. The semiconductor memory device of claim 1, further comprising:
a plurality of insulating supporters passing through the pair of word line pads in the vertical direction.

5. The semiconductor memory device of claim 1, further comprising:
a first insulating block between a first word line pad selected from the pair of word line pads and the second word line at the first vertical level; and
a second insulating block between a second word line pad selected from the pair of word line pads and the first word line at the first vertical level,
wherein the first word line pad is connected to the first word line, and the first word line pad is apart from the second word line in the second lateral direction with the first insulating block therebetween, and
the second word line pad is connected to the second word line, and the second word line pad is apart from the first word line in the second lateral direction with the second insulating block therebetween.

6. The semiconductor memory device of claim 1, further comprising:
a plurality of bit lines extending lengthwise in the vertical direction on the substrate, the plurality of bit lines including a plurality of first bit lines and a plurality of second bit lines, each of the plurality of first bit lines being connected to a corresponding one of the plurality of first active regions, each of the plurality of second bit lines being connected to a corresponding one of the plurality of second active regions,
wherein the plurality of first bit lines are apart from the plurality of second bit lines with the first word line and the second word line therebetween in the first lateral direction.

7. The semiconductor memory device of claim 1, further comprising:
a plurality of bit lines extending lengthwise in the vertical direction on the substrate, wherein each of the plurality of active regions comprises
a vertical protruding local portion having a first thickness in the vertical direction,
a first local portion extending in the first lateral direction from one side of the vertical protruding local portion toward a corresponding one of the plurality of bit lines, the first local portion having a second thickness in the vertical direction, the second thickness being less than the first thickness, and
a second local portion extending in the first lateral direction from another side of the vertical protruding local portion in a direction away from the corresponding on of the plurality of bit lines, the second local portion having a third thickness in the vertical direction, the third thickness being less than the first thickness, and
wherein each of the plurality of bit lines contacts the first local portion of a corresponding one of the plurality of active regions at the first vertical level.

8. The semiconductor memory device of claim 1, wherein
each of the plurality of first active regions and the plurality of second active regions comprises
a vertical protruding local portion having a first thickness in the vertical direction,
a first local portion extending in the first lateral direction from one side of the vertical protruding local portion toward a corresponding one of a plurality of bit lines, the first local portion having a second thickness in the vertical direction, the second thickness being less than the first thickness, and
a second local portion extending in the first lateral direction from another side of the vertical protruding local portion in a direction away from the corresponding one of the plurality of bit lines, the second local portion having a third thickness in the vertical direction, the third thickness being less than the first thickness, and
the first word line surrounds the first local portion of each of the plurality of first active regions, and the second word line surrounds the first local portion of each of the plurality of second active regions.

9. The semiconductor memory device of claim 1, further comprising:
a plurality of first capacitors connected to the plurality of first active regions;
a plurality of second capacitors connected to the plurality of second active regions; and
a plate electrode extending lengthwise in the vertical direction on the substrate, the plate electrode being connected to each of the plurality of first capacitors and the plurality of second capacitors,
wherein the plate electrode is between the plurality of first capacitors and the plurality of second capacitors in the first lateral direction.

10. The semiconductor memory device of claim 1, further comprising:
a plurality of capacitors connected to the plurality of active regions, respectively, each of the plurality of capacitors comprising
a first electrode contacting a corresponding one of the plurality of active regions,
a second electrode apart from the corresponding one of the plurality of active regions, the second electrode covering a surface of the first electrode, and
a dielectric film between the first electrode and the second electrode, wherein each of the plurality of active regions comprises
a vertical protruding local portion having a first thickness in the vertical direction,
a first local portion extending in the first lateral direction from one side of the vertical protruding local portion in a direction away from a corresponding one of the plurality of capacitors, the first local portion having a second thickness in the vertical direction, the second thickness being less than the first thickness, and
a second local portion extending in the first lateral direction from another side of the vertical protruding local portion toward the corresponding one of the plurality of capacitors, the second local portion having a third thickness in the vertical direction, the third thickness being less than the first thickness, and
wherein the first electrode of each of the plurality of capacitors is connected to the second local portion of a corresponding one of the plurality of active regions at the first vertical level.

11. The semiconductor memory device of claim 1, further comprising:
a plurality of bit lines extending lengthwise in the vertical direction on the substrate, each bit line being connected to a corresponding one of the plurality of active regions at the first vertical level; and
a plurality of capacitors being connected to corresponding ones of the plurality of active regions, respectively,
wherein each of the plurality of active regions comprises
a vertical protruding local portion having a first thickness in the vertical direction,
a first local portion connected to a corresponding one of the plurality of bit lines in the first lateral direction from one side of the vertical protruding local portion, the first local portion having a second thickness in the vertical direction, the second thickness being less than the first thickness, and
a second local portion connected to a corresponding one of the plurality of capacitors in the first lateral direction from another side of the vertical protruding local portion, the second local portion having a third thickness in the vertical direction, the third thickness being less than the first thickness, and
wherein a length of the first local portion is greater than a length of the second local portion in the first lateral direction.

12. A semiconductor memory device comprising:
a memory cell block having a three-dimensional (3D) structure, the memory cell block comprising a plurality of memory cells repeatedly arranged on a substrate in a first lateral direction, a second lateral direction, and a vertical direction perpendicular to the substrate, the first lateral direction and the second lateral direction being perpendicular to each other; and
at least one dummy block located around the memory cell block,
wherein the memory cell block comprises
a first active region and a second active region on the substrate at a first vertical level, the first active region and the second active region being apart from each other in the first lateral direction, a thickness of each of the first active region and the second active region varying in the first lateral direction,
a first word line surrounding a portion of the first active region and extending lengthwise in the second lateral direction at the first vertical level,
a second word line surrounding the second active region and extending lengthwise in the second lateral direction at the first vertical level, the second word line being apart from the first word line in the first lateral direction, and
a pair of word line pads being at the first vertical level on the substrate, the pair of word line pads being apart from each other in the second lateral direction with the first word line and the second word line therebetween, the pair of word line pads connected to the first word line and the second word line, respectively, and wherein the at least one dummy block comprises
a plurality of sacrificial layers and a plurality of active layers, which are alternately stacked one-by-one on the substrate in the vertical direction,
each of the plurality of active layers, the first active region, and the second active region comprises a first semiconductor material, and each of the plurality of sacrificial layers comprises a second semiconductor material, the second semiconductor material being different from the first semiconductor material, and
a thickness of each of the plurality of active layers is greater than a thickness of each of the plurality of sacrificial layers in the vertical direction.

13. The semiconductor memory device of claim 12, wherein
when viewed from above a horizontal cross-section of the semiconductor memory device at the first vertical level, the first word line and the second word line are offset from each other in the second lateral direction,
the pair of word line pads comprise a first word line pad and a second word line pad, a first word line pad and a second word line pad being apart from each other in the second lateral direction with the first word line and the second word line therebetween, and
the first word line pad is connected to only the first word line, from among the first word line and the second word line, and the second word line pad is connected to only the second word line, from among the first word line and the second word line.

14. The semiconductor memory device of claim 12, wherein the memory cell block further comprises a plurality of insulating supporters passing through the pair of word line pads in the vertical direction.

15. The semiconductor memory device of claim 12, wherein the memory cell block further comprises:
a first bit line extending lengthwise in the vertical direction on the substrate, the first bit line being connected to the first active region;
a second bit line extending lengthwise in the vertical direction on the substrate, the second bit line being connected to the second active region and apart from the first bit line in the first lateral direction with the first active region and the second active region therebetween;
a first capacitor between the first active region and the second active region in the first lateral direction, the first capacitor being connected to the first active region; and
a second capacitor between the first active region and the second active region in the first lateral direction, the second capacitor being connected to the second active region,
wherein each of the first active region and the second active region comprises
a vertical protruding local portion having a greater thickness than other portions in the vertical direction,
the vertical protruding local portion of the first active region is more adjacent to the first capacitor than the first bit line, and
the vertical protruding local portion of the second active region is more adjacent to the second capacitor than the second bit line.

16. The semiconductor memory device of claim 12, further comprising:
a first capacitor between the first active region and the second active region in the first lateral direction, the first capacitor being connected to the first active region;
a second capacitor between the first active region and the second active region in the first lateral direction, the second capacitor being connected to the second active region; and
a plate electrode between the first capacitor and the second capacitor in the first lateral direction, the plate electrode being connected to each of the first capacitor and the second capacitor.

17. The semiconductor memory device of claim 12, wherein, in the at least one dummy block, each of the plurality of sacrificial layers comprises an undoped silicon germanium (SiGe) layer or a SiGe layer doped with carbon (C) atoms, and each of the plurality of active layers comprises a silicon (Si) layer.

18. A semiconductor memory device comprising:
a memory cell block having a three-dimensional (3D) structure, the memory cell block comprising a plurality of memory cells repeatedly arranged on a substrate in a first lateral direction, a second lateral direction, and a vertical direction perpendicular to the substrate, the first lateral direction and the second lateral direction being perpendicular to each other; and
at least one dummy block located around the memory cell block,
wherein the memory cell block comprises
a plurality of active regions repeatedly arranged at a vertical level on the substrate in the first lateral direction and the second lateral direction, a thickness of each of the plurality of active regions in the vertical direction varying in the first lateral direction, the plurality of active regions including a first group of active regions and a second group of active regions,
a first word line surrounding the first group of active regions, the first word line extending lengthwise in the second lateral direction at a first vertical level, the first group of active regions being selected from the plurality of active regions and arranged in a line in the second lateral direction,
a second word line surrounding the second group of active regions, the second word line extending lengthwise in the second lateral direction at the first vertical level, the second group of active regions being selected from the plurality of active regions and arranged in a line in the second lateral direction, the second word line being apart from the first word line in the first lateral direction,
a first word line pad and a second word line pad being apart from each other in the second lateral direction with first word line and the second word line therebetween at the first vertical level,
a plurality of bit lines extending lengthwise in the vertical direction on the substrate, the plurality of bit lines being connected to corresponding ones of the plurality of active regions, respectively, at the first vertical level, and
a plurality of capacitors connected to corresponding ones of the plurality of active regions, respectively,
wherein, when viewed from above a horizontal cross-section of the memory block at the first vertical level, the first word line and the second word line are offset from each other in the second lateral direction, and
wherein the at least one dummy block comprises a plurality of sacrificial layers and a plurality of active layers, which are alternately stacked one-by-one on the substrate in the vertical direction, each of the plurality of sacrificial layers comprises a silicon (Si) layer, an undoped silicon germanium (SiGe) layer, or a SiGe layer doped with carbon (C) atoms, each of the plurality of active layers comprises a Si layer, and a thickness of each of the plurality of active layers is greater than a thickness of each of the plurality of sacrificial layers in the vertical direction.

19. The semiconductor memory device of claim 18, wherein
each of the first group of active regions and the second group of active regions comprises
a vertical protruding local portion having a first thickness in the vertical direction,
a first local portion extending in the first lateral direction from one side of the vertical protruding local portion, the first local portion being connected to a corresponding one of the plurality of bit lines, the first local portion having a second thickness in the vertical direction, the second thickness being less than the first thickness, and
a second local portion extending in the first lateral direction from another side of the vertical protruding local portion, the second local portion being connected to a corresponding one of the plurality of capacitors, the second local portion having a third thickness in the vertical direction, the third thickness being less than the first thickness, and
the first word line surrounds the first local portion of each of the first group of active regions, and the second word line surrounds the first local portion of each of the second group of active regions.

20. The semiconductor memory device of claim 18, further comprising:
a plurality of insulating supporters passing through the first word line pad and the second word line pad in the vertical direction.
